(19) United States
(12) Patent Application Publication
(10) Pub. No.: US 2025/0006571 A1
(43) Pub. Date: Jan. 2, 2025

(54) METHODS AND APPARATUS FOR STACKS OF GLASS LAYERS INCLUDING THIN FILM CAPACITORS

(71) Applicant: Intel Corporation, Santa Clara, CA (US)

(72) Inventors: Gang Duan, Chandler, AZ (US); Minglu Liu, Chandler, AZ (US); Srinivas Venkata Ramanuja Pietambaram, Chandler, AZ (US)

(73) Assignee: Intel Corporation, Santa Clara, CA (US)

(21) Appl. No.: 18/883,861

(22) Filed: Sep. 12, 2024

(51) Int. Cl. H01L 23/15; H01L 23/538

(52) U.S. Cl. CPC H01L 23/15; H01L 23/5385; H01L 28/40

(57) ABSTRACT

Systems, apparatus, articles of manufacture, and methods for stacks of glass layers including thin film capacitors are disclosed. An example substrate includes a first glass layer, a dielectric layer on the first glass layer, a second glass layer, the first glass layer between the dielectric layer and the second glass layer, and a capacitor in the layer.

### BACKGROUND

Integrated circuit (IC) chips and/or semiconductor dies are routinely connected to larger circuit boards such as motherboards and other types of printed circuit boards (PCBs) via a package substrate. As IC chips and/or dies reduce in size and interconnect densities increase, alternatives to traditional substrate layers are being developed to provide stable transmission of high-frequency data signals between different circuitry and/or increased power delivery. One option being pursued is the implementation of package substrates with glass cores. Generally, glass core implementations offer several advantages compared to implementations with conventional epoxy cores, including a higher plated through-hole (PTH) density, lower signal losses, and lower total thickness variation.

### BRIEF DESCRIPTION OF THE DRAWINGS

FIG. 1 illustrates an example integrated circuit (IC) package constructed in accordance with teachings disclosed herein.

FIG. 2A illustrates an example first substrate core that may be used to implement the example substrate core of FIG. 1.

FIG. 2B illustrates an example second substrate core that may be used to implement the example substrate core of FIG. 1.

FIG. 2C illustrates an example third substrate core that may be used to implement the example substrate core of FIG. 1.

FIG. 2D illustrates an example fourth substrate core that may be used to implement the example substrate core of FIG. 1.

FIGS. 3-12 illustrate different intermediate stages in an example fabrication process to manufacture the example substrate cores of FIGS. 2A-2D.

FIG. 13 illustrates an intermediate stage in an example fabrication process to manufacture the example first substrate core of FIG. 2A.

FIG. 14 illustrates an intermediate stage in an example fabrication process to manufacture the example second substrate core of FIG. 2B.

FIG. 15 illustrates an intermediate stage in an example fabrication process to manufacture the example second substrate core of FIG. 2C.

FIG. 16 illustrates an intermediate stage in an example fabrication process to manufacture the example third substrate core of FIG. 2D.

FIG. 17 is flowchart representative of example methods that may be performed to fabricate any one of the substrate cores of FIGS. 2A-2B.

FIG. 18 is a top view of a wafer including dies that may be included in an IC package constructed in accordance with teachings disclosed herein.

FIG. 19 is a cross-sectional side view of an IC device that may be included in an IC package constructed in accordance with teachings disclosed herein.

FIG. 20 is a cross-sectional side view of an IC device assembly that may include an IC package constructed in accordance with teachings disclosed herein.

FIG. 21 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

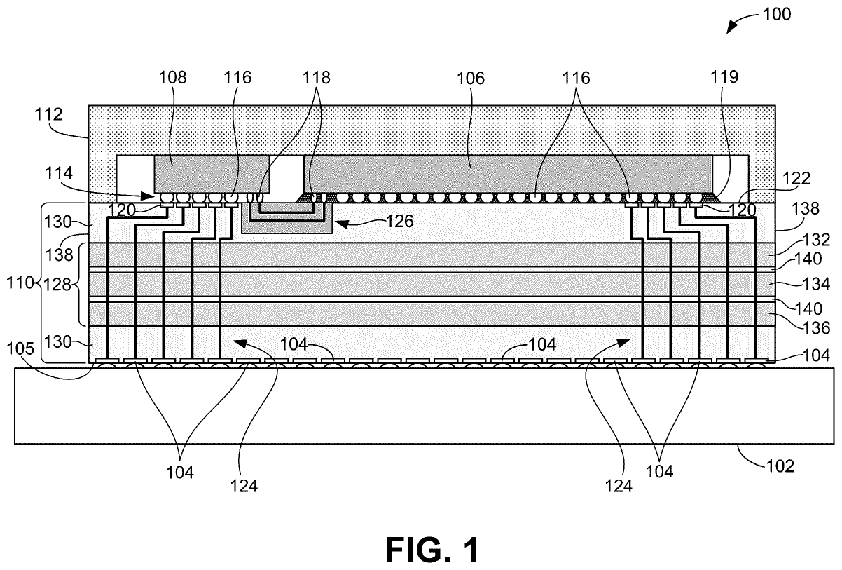

FIG. 1 illustrates an example integrated circuit (IC) package 100 constructed in accordance with teachings disclosed herein. In the illustrated example, the IC package 100 is electrically coupled to a circuit board 102 via an array of lands 104 (also referred to herein as contact pads) on a bottom surface 105 (e.g., a bottom external surface, a mounting surface, etc.) of the package. In some examples, the IC package 100 may include balls, pins, and/or pads, in addition to or instead of the lands 104, to enable the electrical coupling of the IC package 100 to the circuit board 102. In this example, the IC package 100 includes two semiconductor dies 106, 108 (e.g., silicon dies, etc.) (sometimes also referred to as chips or chiplets) that are mounted to a package substrate 110 and enclosed by a package lid or mold compound 112. Thus, the package substrate 110 is an example means for supporting a semiconductor die. While the example IC package 100 of FIG. 1 includes two dies 106, 108, in other examples, the IC package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

As shown in the illustrated example, each of the dies 106, 108 is electrically and mechanically coupled to the package substrate 110 via corresponding arrays of interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the package substrate 110 (e.g., the interconnects 114) are sometimes referred to as first level interconnects. By contrast, the electrical connections between the IC package 100 and the circuit board 102 (e.g., the lands 104, etc.) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps corresponding to core bumps 116 and bridge bumps 118. As used herein, the core bumps 116 are bumps on the dies 106, 108 through which electrical signals pass between the dies 106, 108 and components external to the IC package 100. More particularly, as shown in the illustrated example, when the dies 106, 108 are mounted to the package substrate 110, the core bumps 116 are physically connected and electrically coupled to contact pads 120 on an inner surface 122 of the package substrate 110. The contact pads 120 on the inner surface 122 of the package substrate 110 are electrically coupled to the lands 104 on the bottom surface 105 (e.g., the bottom external surface, etc.) of the package substrate 110 (e.g., a surface opposite the inner surface 122) via internal interconnects 124 within the package substrate 110. As a result, there is a continuous electrical signal path between the core bumps 116 of the dies 106, 108 and the lands 104 mounted to the circuit board 102 that pass through the contact pads 120 and the interconnects 124 provided therebetween.

As used herein, the bridge bumps 118 are bumps on the dies 106, 108 through which electrical signals pass between different ones of the dies 106, 108 within the IC package 100. Thus, as shown in the illustrated example, the bridge bumps 118 of the first die 106 are electrically coupled to the bridge bumps 118 of the second die 108 via an interconnect bridge 126 (e.g. silicon-based interconnect die, etc.) embedded in the package substrate 110. As represented in FIG. 1, core bumps 116 are typically larger than bridge bumps 118. In some examples, the interconnect bridge 126 and the associated bridge bumps 118 are omitted.

In some examples, an underfill material 119 is disposed between the dies 106, 108 and the package substrate 110 around and/or between the first level interconnects 114 (e.g., around and/or between the core bumps 116 and/or the bridge bumps 118). In the illustrated example, only the first die 106 is associated with the underfill material 119. However, in other examples, both dies 106, 108 are associated with the underfill material 119. In other examples, the underfill material 119 is omitted. In some examples, the mold compound 112 is used as an underfill material that surrounds the first level interconnects 114.

In some examples, the IC package 100 includes additional passive components, such as surface-mount resistors, capacitors, and/or inductors disposed on the bottom surface 105 of the package substrate 110 and/or the inner surface 122 (e.g., the top surface, etc.) of the package substrate 110.

In FIG. 1, the package substrate 110 of the example IC package 100 includes a substrate core 128 (e.g., a main core, an overall core) between two separate build-up regions 130 (e.g., build-up layers, redistribution layers). As shown in the illustrated example, the substrate core 128 includes multiple distinct glass cores (e.g., multiple glass layers, multiple glass core layers, etc.), namely an example top glass core 132 (e.g., a first glass core, etc.), an example middle glass core 134 (e.g., a second glass core, etc.), and an example bottom glass core 136 (e.g., a third glass core, etc.). In the illustrated example of FIG. 1, the glass cores 132, 134, 136 (e.g., sub-cores, glass substrates, glass layers, glass sheets, etc.) are vertically stacked on top of one another. That is, in the illustrated example of FIG. 1, the glass cores 132, 134, 136 are vertically aligned (e.g., the glass cores 132, 134, 136 are vertically aligned glass layers, etc.).

In some examples, the glass cores 132, 134, 136 include at least one of: aluminosilicate, borosilicate, alumino-borosilicate, silica, and/or fused silica. In some examples, the glass cores 132, 134, 136 include one or more additives including: aluminum oxide (Al₂O₃), boron trioxide (B₂O₃), magnesia oxide (MgO), calcium oxide (CaO), stoichiometric silicon oxide (SrO), barium oxide (BaO), stannic oxide (SnO₂), nickel alloy (Na₂O), potassium oxide (K₂O), phosphorus trioxide (P₂O₃), zirconium dioxide (ZrO₂), lithium oxide (Li₂O), titanium (Ti), and/or zinc (Zn). In some examples, the glass cores 132, 134, 136 include silicon and oxygen. In some examples, the glass cores 132, 134, 136 include silicon, oxygen, and/or one or more of aluminum, boron, magnesium, calcium, barium, tin, sodium, potassium, strontium, phosphorus, zirconium, lithium, titanium, and/or zinc. In some examples, the glass cores 132, 134, 136 include at least 23 percent silicon by weight and at least 26 percent oxygen by weight. In some examples, the glass cores 132, 134, 136 are individual layers of glass including silicon, oxygen, and aluminum. In some examples, the glass cores 132, 134, 136 include at least 23 percent silicon by weight, at least 26 percent oxygen by weight, and at least 5 percent aluminum by weight.

In some examples, the glass cores 132, 134, 136 are amorphous solid glass layers. In some examples, the glass cores 132, 134, 136 are layers of glass that do not include an organic adhesive or an organic material. In some examples, the glass cores 132, 134, 136 are solid layers of glass having a same rectangular shape in plan view. In other examples, some or all of the glass cores 132, 134, 136 have different shapes. In some examples, the glass cores 132, 134, 136, as glass substrates, include at least one glass layer and do not include epoxy and do not include glass fibers (e.g., do not include an epoxy-based prepreg layer with glass cloth). In some examples, the glass cores 132, 134, 136 correspond to single pieces of glass that extend the full height/thickness of each corresponding core.

In some examples, the glass cores 132, 134, 136 have a rectangular shape that is substantially coextensive, in plan view, with the layers above and/or below the core. In some examples, the glass cores 132, 134, 136 have a thickness in a range of about 25 micrometers (μm) to about 400 μm (with the overall thickness of the substrate core 128 ranging from about 50 μm to about 1.4 millimeters (mm)). In some examples, the glass cores 132, 134, 136 can have dimensions of about 10 mm on a side to about 250 mm on a side (e.g., 10 mm by 10 mm to 250 mm by 250 mm). In some examples, the glass cores 132, 134, 136 correspond to rectangular prism volumes with sections (e.g., vias) removed and filled with other materials (e.g., metal).

The build-up regions 130 are represented in FIG. 1 as masses/blocks with the internal interconnects 124 extending in straight lines through the build-up regions 130 (and the glass cores 132, 134, 136). However, FIG. 1 has been simplified for the sake of clarity and purposes of explanation. In practice, the interconnects are not necessarily straight. More particularly, in some examples, the build-up regions 130 are defined by alternating layers of dielectric material and layers of conductive material (e.g., a metal such as copper, etc.). The conductive (metal) layers serve as the basis for the internal interconnects 124 represented, in a simplified form, by straight lines as shown in FIG. 1. In some examples, the metal layers are patterned to define electrical routing or conductive traces that are electrically coupled between different metal layers by conductive (e.g., metal) vias extending through intervening dielectric layers. Further, the electrical routing or traces on either side of the substrate core 128 may be electrically coupled by through-glass vias (TGVs) (e.g., copper plated vias) extending through the glass cores 132, 134, 136.

Among other things, glass cores are advantageous over epoxy-based cores because glass is stiffer and, therefore, provides greater mechanical support or strength for the package substrate. Thus, the substrate core 128 and, more particularly, the individual ones of the glass cores 132, 134, 136 are example means for strengthening the package substrate. In addition to mechanical benefits, glass cores also provide other advantages including a higher plated through-hole (PTH) density, lower signal losses, and a lower total thickness variation. However, glass cores also present challenges due to the fragile (e.g., brittle) nature of glass and the possibility of defects that can develop into cracks that propagate through the glass.

A common type of failure of known glass cores is referred to as a seware failure. Seware failures result in the separation of a glass core along a crack that propagates from an edge of the glass core along its length and width between the main outer surfaces (e.g., upper and lower surfaces, front and back surfaces) of the glass core. That is, seware failures are characterized by a glass core being split into two separate sheets of glass along a line extending generally parallel to the main plane of the glass core.

Factors that contribute to seware failures include defects on the edges of glass cores resulting from singulation and the internal stress induced by a mismatch in coefficient of thermal expansion (CTE) between the glass core and the material in the build-up regions during thermal cycles of the package substrate 110. More particularly, package substrates, such as the package substrate 110 of FIG. 1, are often fabricated on a large panel that is subsequently singulated or cut into individual units with a saw. Thus, in the illustrated example of FIG. 1, the package substrate 110, including the substrate core 128 (and the associated glass cores 132, 134, 136) and the build-up regions 130, include opposing edges 138 that are created by the cut of a saw. Such sawing can result in defects developing on the edges of glass cores (e.g., the edges 138 of the glass cores 132, 134, 136 in FIG. 1) that can give rise to cracks that propagate laterally across the middle of the glass core to split the glass core in two. The development and propagation of cracks in this manner are exacerbated by stress induced by fluctuations in temperature and the difference in CTE of the build-up regions relative to the CTE of the glass core. Generally, the material in the build-up regions 130 has a higher CTE than glass. As a result, the material in the build-up regions 130 expands and contracts more than a glass core in response to thermal fluctuations, thereby causing internal stress within the glass core that can promote crack propagation.

Examples disclosed herein reduce (minimize) concerns for seware failures by implementing the substrate core 128 of the substrate with multiple distinct (e.g., disaggregated, etc.) glass cores (e.g., the glass cores 132, 134, 136, etc.) stacked on top of one another as shown in FIG. 1. More particularly, in examples disclosed herein, the glass cores 132, 134, 136 are implemented by different materials (or different compositions of the same materials) associated with different CTEs. In some examples, the glass cores that are closer to the build-up regions 130 are fabricated with a CTE that is closer to the CTE of the build-up regions 130 than the CTE of the glass cores farther away from the build-up regions 130 (e.g., closer to the middle of the stack of glass cores). In this manner, the substrate core 128 is defined by a gradation of CTEs or incremental changes in CTE (between each of the glass cores 132, 134, 136) that provide a transition between the different layers in the package substrate 110 to reduce stress at any given location. Thus, in some examples, the middle glass core 134 has a lower CTE than the top glass core 132 and a lower CTE than the bottom glass core 136. In some examples, the CTE of the top glass core 132 and the bottom glass core 136 are the same. Thus, in some examples, the different CTEs of the glass cores 132, 134, 136 are symmetrical across the overall thickness of the substrate core 128. That is, the arrangement or ordering of the stack of glass cores 132, 134, 136 and their associated CTEs define a symmetric sequence of CTEs from a lowermost glass core (e.g., the bottom glass core 136) to an uppermost glass core (e.g., the top glass core 132). In other examples, the different CTEs may not be symmetrical.

In addition to implementing multiple glass cores with different CTEs to reduce stress, in some examples, a buffer material 140 (e.g., adhesive material) is disposed between adjacent ones of the glass cores 132, 134, 136 to hold the glass cores together. In some such examples, the buffer material 140 has a relatively low modulus of elasticity to absorb stress resulting from thermal fluctuations and the different CTEs of the glass cores 132, 134, 136, thereby further reducing stress internal to the substrate core 128. In some examples, the buffer material is an organic dielectric material (e.g., polyimide, parylene, etc.). In some examples, the buffer material is an inorganic dielectric material (e.g., silicon oxide (SiOx), silicon nitride (SiNₓ)). In some examples, the buffer material includes a carbon doped oxide (CDO). In some examples, one or more of the layers of the buffer material 140 may be omitted such that different ones of the glass cores 132, 134, 136 are directly abutting. In some examples, the layers of the buffer material 140 include conductive material that facilitates the redistribution of electrical paths between the glass cores 132, 134, 136. Thus, the materials between the glass cores are also referred to herein as redistribution material that defines one or more redistribution layers in the package substrate 110.

Although three different glass cores (e.g., the glass cores 132, 134, 136, etc.) are shown in the example substrate core 128 of FIG. 1, any other suitable number of glass cores may be implemented with corresponding CTEs to define a particular CTE gradient across the overall thickness of the substrate core 128. Thus, in some examples, only two glass cores, each with a different CTE, are employed. In other examples, more than three glass cores are employed. In some such examples, each glass core is different than every other glass core in the stack of cores. In other examples, two or more of the glass cores may have the same CTE (e.g., made from the same materials with the same composition) with at least one glass core having a different CTE than the others.

In the illustrated example of FIG. 1, each of the glass cores 132, 134, 136 is shown as having the same thickness (e.g., an approximately equal thickness, etc.). However, in some examples, the thickness of the glass cores 132, 134, 136 may differ from one another. For instance, in some examples, the middle glass core 134 is thicker than the top glass core 132 and thicker than the bottom glass core 136. In other examples, the middle glass core 134 is thinner than the top glass core 132 and thinner than the bottom glass core 136. Any suitable thickness(es) for the glass cores can be implemented to achieve a suitable CTE gradient that reduces stress to mitigate against to seware failures while also providing sufficient rigidity for the package substrate.

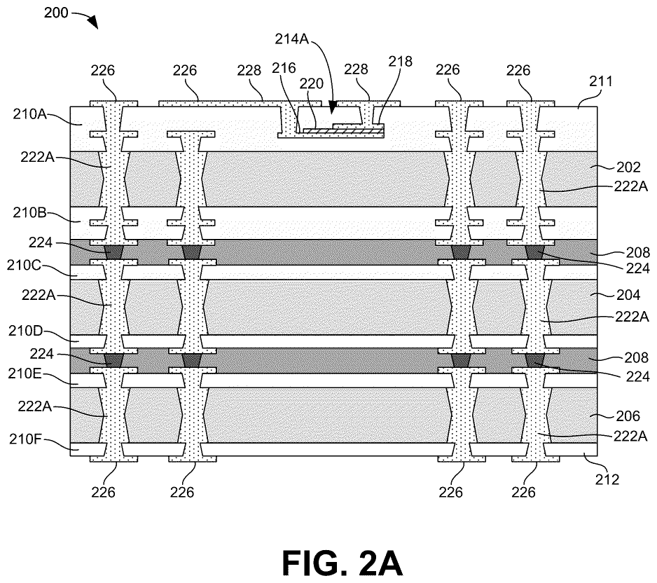

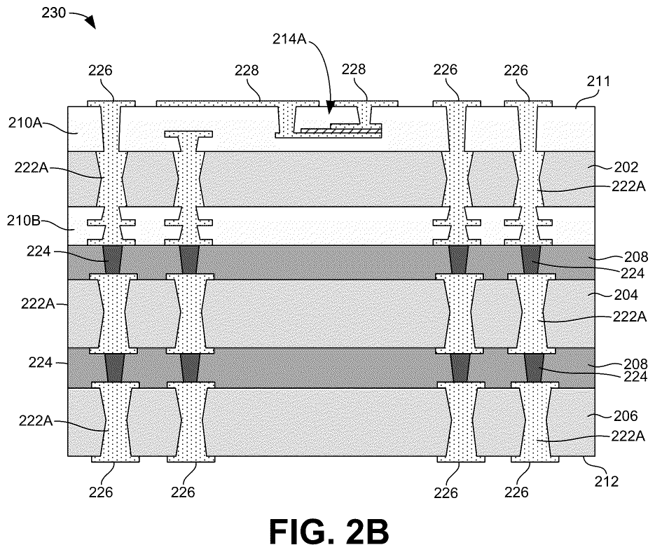

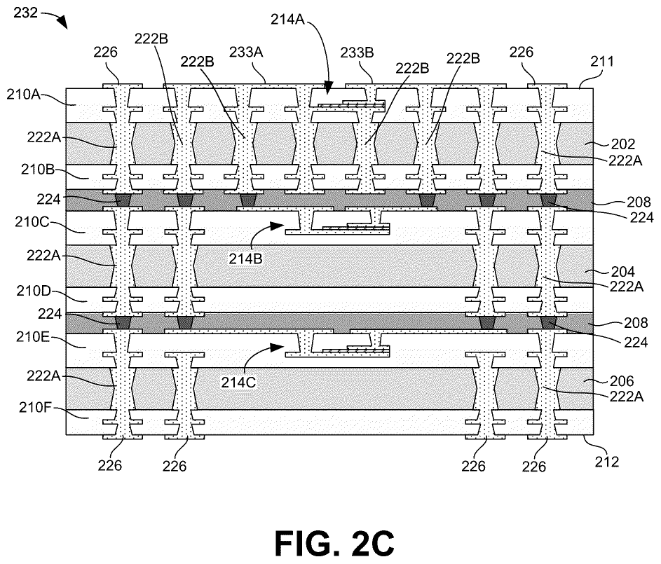

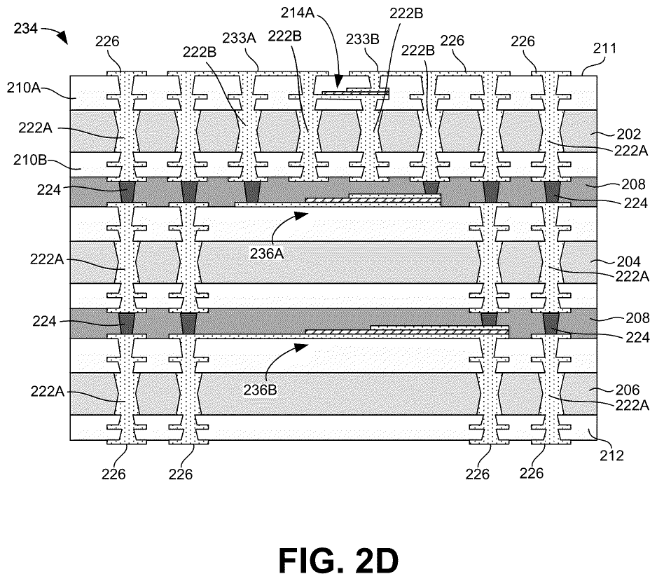

The stacking of multiple glass cores 132, 134, 136 with different CTEs as disclosed herein can serve to reduce stress that may otherwise lead to seware failures. The example substrate cores disclosed herein also include thin film capacitors embedded therein. Example substrate cores disclosed herein include thin film capacitors to improve power delivery to components coupled to the package substrates, such as the dies 106, 108 of FIG. 1. Some example substrate cores disclosed herein include a thin film capacitor above an uppermost one of the stacked glass cores. Other example substrate cores disclosed herein include thin film capacitors disposed between or above two or more of the stacked glass cores. Some example substrate cores disclosed herein include thin film capacitors embedded in (e.g., encompassed by) redistribution layers (RDLs) on and/or between ones of the stacked glass cores. Some example substrate cores disclosed herein include thin film capacitors disposed directly on one or more of the stacked glass cores. Example substrate cores including embedded thin film capacitors are described below in conjunction with FIGS. 2A-2D.

FIG. 2A illustrates an example first substrate core 200 that may be used to implement the example substrate core 128 of FIG. 1. Similar to FIG. 1, the first substrate core 200 of FIG. 2 includes an example first glass core 202, an example second glass core 204, and an example third glass core 206 that are stacked on top of one another. In this example, the glass cores 202, 204, 206 correspond to the glass cores 132, 134, 136 of FIG. 1, respectively. Thus, the glass cores 202, 204, 206 are vertically aligned and include different CTEs as described above. For instance, in some examples, the second glass core 204 (e.g., the middle glass core) has a lower CTE than either the first glass core 202 or the third glass core 206. In this example, each of the glass cores 202, 204, 206 have approximately the same thickness. In some examples, the thickness is approximately 350 micrometers (μm). In other examples, the thickness can be greater or less than 350 μm. Further, in some examples, different ones of the glass cores 202, 204, 206 can have different thicknesses. Additionally, while three glass cores are shown, in some examples, any other suitable number of glass cores (e.g., 2, 4, 5, 6, 7, etc.) may be employed. In such examples, the stack of glass cores can define any suitable CTE gradient based on differences in the CTE for each glass core in the stack. In some examples, the CTE gradient is symmetrical across the overall thickness of the first substrate core 200. In other examples, the CTE gradient may not be symmetrical.

In the illustrated example of FIG. 2A, the glass cores 202, 204, 206 are separated by intervening layers of adhesive dielectric 208 (e.g., buffer material, adhesive material, etc.). In some examples, the adhesive dielectric 208 includes an organic epoxy-based dielectric. However, any other suitable dielectric may additionally or alternatively be used. In some examples, the adhesive dielectric 208 couples corresponding ones of the glass cores 202, 204, 206 together. For example, the layer of the adhesive dielectric 208 between the first glass core 202 and the second glass core 204 adhesively couples the first glass core 202 to the second glass core 204, etc.

In the illustrated example of FIG. 2A, the first substrate core 200 includes an example first redistribution layer 210A, an example second redistribution layer 210B, an example third redistribution layer 210C, an example fourth redistribution layer 210D, an example fifth redistribution layer 210E, and an example sixth redistribution layer 210F. The redistribution layers 210A, 210B, 210C, 210D, 210E, 210F include a dielectric filler material (e.g., Ajinomoto build-up film (ABF), etc.) and one or more conductive interconnections (e.g., vias, pads, bumps, etc.) disposed therein. The conductive interconnections of the redistribution layers 210A, 210B, 210C, 210D, 210E, 210F transmit power and/or electrical signals between adjacent ones of the glass cores 202, 204, 206. In the illustrated example of FIG. 2A, the first redistribution layer 210A and the sixth redistribution layer 210F are on the outermost surfaces of the outermost glass cores (e.g., the first glass core 202 and third glass core 206). Thus, in the illustrated example of FIG. 2A, the first redistribution layer 210A and the sixth redistribution layer 210F define an example first outer surface 211 and an example second outer surface 212 of the first substrate core 200.

In some examples, some or all of the redistribution layers 210A, 210B, 210C, 210D, 210E, 210F are absent. In such examples, corresponding ones of the glass cores 202, 204, 206 directly abut a corresponding layer of the adhesion dielectric 208. An example substrate core in which the second redistribution layer 210B, the third redistribution layer 210C, the fourth redistribution layer 210D, the fifth redistribution layer 210E, and the sixth redistribution layer 210F are absent is described below in conjunction with FIG. 2B. In some such examples, the first redistribution layer 210A and the sixth redistribution layer 210F shown in FIG. 2A may be omitted and/or correspond to a first layer of build-up regions (e.g., the build-up regions 130 of FIG. 1) on either side of the first substrate core 200. In such examples, the outer surfaces of the first glass core 202 and third glass core 206 define the first outer surface 211 and the second outer surface 212 of the first substrate core 200.

In the illustrated example of FIG. 2A, the first substrate core 200 includes an example thin film capacitor 214A embedded in the first redistribution layer 210A. The thin film capacitor 214A can be implemented by a metal-insulator-metal capacitor (“MIMCAP”), a metal-oxide-metal capacitor (“MOMCAP”), and/or another suitable type of capacitor. In the illustrated example of FIG. 2A, the first thin film capacitor 214A includes an example bottom electrode layer 216, an example top electrode layer 218, and an example dielectric layer 220. The electrode layers 216, 218 of the thin film capacitor 214A are thin films that can be composed of any suitable electrically conductive material(s), including copper, aluminum, nickel, gold, and silver, etc. In some examples, the electrode layers 216, 218 can be composed of multiple material(s). The dielectric layer 220 is a thin film layer separating the electrode layers 216, 218 that can be composed of a plastic film and/or another suitable dielectric material (e.g., a high-k dielectric). In various examples, electrode layers 216, 218 can comprise titanium, tantalum, ruthenium, or other metallic elements. Additionally, in some examples, the dielectric layer 220 can contain (e.g., be composed of, etc.) dielectrics, amorphous or otherwise, including hafnium oxides, silicon oxides, silicon nitrides, tantalum oxides, aluminum oxides, and other materials such as barium strontium titanate, barium titanate, lead zirconium titanate, tantalum titanate, lead lanthanum titanate, strontium titanate, barium strontium niobate, barium zirconium titanate or barium titanium niobate, etc. In some examples, the thin film capacitor 214A facilitates power delivery to features coupled to the first substrate core 200 (e.g., the dies 106, 108 of FIG. 1, etc.), power storage from the first substrate core 200, filtering, and/or other functionality associated with capacitors. In the illustrated example of FIG. 2A, the thin film capacitor 214A is spaced from the first glass core 202 and the outer surface 211. In other examples, the thin film capacitor 214A abuts the glass core 202 and/or the outer surface 211.

In the illustrated example of FIG. 2A, the first substrate core 200 includes a single thin film capacitor (e.g., the thin film capacitor 214A, etc.). In other examples, the first substrate core 200 can include additional thin film capacitors in the first redistribution layer 210A (e.g., two thin film capacitors, three thin film capacitors, etc.). Additionally or alternatively, the first substrate core 200 can include additional thin film capacitors between the first glass core 202 and the second glass core 204 and/or between the second glass core 204 and the third glass core 206. Example substrate cores including thin film capacitors between the glass cores 202, 204, 206 are described below in conjunction with FIGS. 2C and 2D.

In the illustrated example of FIG. 2A, the glass cores 202, 204, 206 also include example first through glass vias (TGVs) 222A that are electrically coupled by additional conductive material 224 extending through the intervening layers of the adhesive dielectric 208. In the illustrated example of FIG. 2A, the TGVs 222A are adjacent to the lateral edges of the first substrate core 200. That is, in the illustrated example of FIG. 2A, the center of the first substrate core 200 does not include TGVs. In other examples, the first substrate core 200 can include other arrangements of TGVs 222A and thin film capacitors (e.g., the thin film capacitor 214A, etc.). For example, the thin film capacitor 214A can be disposed near one of the lateral edges and the TGVs 222A can be disposed near the center of the first substrate core 200. In such examples, like the illustrated example of FIG. 2A, the TGVs 222A are not vertically aligned with regions of the first substrate core 200 that include a thin film capacitor (e.g., the thin film capacitor 214A, etc.). In the illustrated example of FIG. 2A, the interconnections of the redistribution layers 210B, 210C, 210D, 210E couple vertically aligned ones of the TGVs 222A. In other examples, the interconnections of the redistribution layers 210B, 210C, 210D, 210E can redistribute (e.g., split, merge, redirect, etc.) the electrical connections between the TGVs 222A. That is, the redistribution layers 210B, 210C, 210D, 210E enable non-vertically aligned ones of the TGVs 222A to be electrically coupled. In some examples, the TGVs 222A are plated with the same material as used in the additional conductive material 224 (e.g., copper paste, plated copper pads, liquid metal (LM) paste, etc.). In some examples, at least some of the additional conductive material 224 may contain a different material than the TGVs 222A. In the illustrated example of FIG. 2A, the first substrate core 200 includes example first conductive pads 226 that are positioned on the outer surfaces 211, 212 of the first substrate core 200 and electrically coupled to the TGVs 222A and the additional conductive material 224. In this example, the conductive pads 226 define opposite ends of interconnects (e.g., portions of the interconnects 124 of FIG. 1) extending the full thickness of the first substrate core 200. In the illustrated example of FIG. 2A, the first substrate core 200 includes example second conductive pads 228 that are electrically coupled to the thin film capacitor 214A. In some examples, the second conductive pads 228 can be coupled to corresponding interconnections within the build-up region 130 of FIG. 1 to enhance power distribution to dies 106, 108. In some examples, one or more of the second conductive pads 228 and one or more first conductive pads 226 can be implemented by one or more same electrical pad(s). That is, a single electrical pad can be coupled to one of the electrode layers 216, 218 and one of the TGVs 222A.

FIG. 2B illustrates an example second substrate core 230 that may be used to implement the example substrate core 128 of FIG. 1. In the illustrated example of FIG. 2B, the second substrate core 230 includes the glass cores 202, 204, 206 of FIG. 2A, the adhesive dielectric 208 of FIG. 2A, the first redistribution layer 210A of FIG. 2A, the second redistribution layer 210B of FIG. 2A, the outer surfaces 211, 212 of FIG. 2A, the thin film capacitor 214A of FIG. 2A, the TGVs 222A of FIG. 2A, the additional conductive material 224 of FIG. 2A, and the conductive pads 226, 228 of FIG. 2A. The second substrate core 230 of FIG. 2B is similar to the first substrate core 200 of FIG. 2A, except that the second substrate core 230 does not include the third redistribution layer 210C of FIG. 2A, the fourth redistribution layer 210D of FIG. 2A, the fifth redistribution layer 210E of FIG. 2A, and the sixth redistribution layer 210F of FIG. 2A.

In the illustrated example of FIG. 2B, a top surface of the second glass core 204 directly abuts the dielectric material (e.g., the adhesive dielectric 208, etc.) separating the first glass core 202 and the second glass core 204. In the illustrated example of FIG. 2B, a bottom surface of the second glass core 204 and a top surface of the third glass core 206 directly contact (e.g., abut, etc.) the adhesive dielectric 208. In the illustrated example of FIG. 2B, the second outer surface 212 of the second substrate core 230 is defined by the bottom surface of the third glass core 206. In the illustrated example of FIG. 2B, ones of the conductive pads 226 on the second outer surface 212 abut the third glass core 206. Unlike the first substrate core 200 of FIG. 2A, the second substrate core 230 does not facilitate the redistribution of electrical signals between the second glass core 204 and the third glass core 206, but can have a reduced thickness and/or simplified manufacturing process (e.g., the fabrication of the redistribution layers 210C, 210D, 210E, 210F are omitted, etc.) when compared to the first substrate core 200 of FIG. 2A.

FIG. 2C illustrates an example third substrate core 232 that may be used to implement the example substrate core 128 of FIG. 1. In the illustrated example of FIG. 2C, the third substrate core 232 includes the glass cores 202, 204, 206 of FIGS. 2A and 2B, the adhesive dielectric 208 of FIGS. 2A and 2B, the redistribution layers 210A, 210B, 210C, 210D, 210E, 210F of FIGS. 2A and 2B, the outer surfaces 211, 212 of FIGS. 2A and 2B, the thin film capacitor 214A of FIGS. 2A and 2B (referred to as the first thin film capacitor 214A in conjunction with FIGS. 2C and 2D), the TGVs 222A of FIGS. 2A and 2B, the additional conductive material 224 of FIGS. 2A and 2B, and the conductive pads 226 of FIGS. 2A and 2B. The third substrate core 232 of FIG. 2C is similar to the first substrate core 200 of FIG. 2A, except as noted otherwise. In the illustrated example of FIG. 2C, the third substrate core 232 includes an example second thin film capacitor 214B embedded in the third redistribution layer 210C and an example third thin film capacitor 214C embedded in the fifth redistribution layer 210E. The second thin film capacitor 214B and the third thin film capacitor 214C are similar to the first thin film capacitor 214A, except as noted otherwise. In the illustrated example of FIG. 2C, each of the thin film capacitors 214A, 214B, 214C is electrically coupled between a third electrical pad 233A and a fourth electrical pad 233B.

In the illustrated example of FIG. 2C, the third substrate core 232 includes example second TGVs 222B. The second TGVs 222B are similar to the first TGV 222A, except as noted otherwise. In other examples, the second TGVs 222B can be disposed at a different location in the third substrate core 232 (e.g., depending on the position and/or configuration of the thin film capacitors 214A, 214B, 214C, etc.). In the illustrated example of FIG. 2C, the second glass core 204 and the third glass core 206 do not include TGVs disposed in the center thereof (e.g., TGVs between the first TGVs 222A, etc.). In other examples, the second glass core 204 and the third glass core 206 include TGVs similar to the second TGVs 222B.

In the illustrated example of FIG. 2C, the third electric pad 233A is coupled to the bottom electrode layer of each of the thin film capacitors 214A, 214B, 214C (e.g., a bottom electrode layer similar to the bottom electrode layer 216 of FIG. 2A, etc.). In the illustrated example of FIG. 2C, the fourth electric pad 233B is coupled to the top electrode layer of each of the thin film capacitors 214A, 214B, 214C (e.g., a bottom electrode layer similar to the top electrode layer 218 of FIG. 2A, etc.). In the illustrated example of FIG. 2C, the interconnections of the first redistribution layer 210A electrically couple the first thin film capacitor 214A to the pads 233A, 233B. In the illustrated example of FIG. 2C, the interconnections of the first redistribution layer 210A electrically couple the third film capacitor 214C to the pads 233A, 233B. In the illustrated example of FIG. 2C, ones of the second TGVs 222B electrically couple the second film capacitor 214B to the pads 233A, 233B. In the illustrated example of FIG. 2C, ones of the first TGVs 222A electrically couple the third film capacitor 214C to the pads 233A, 233B. In the illustrated example of FIG. 2C, each of the thin film capacitors 214A, 214B, 214C is electrically coupled between a third electrical pad 233A and a fourth electrical pad 233B in parallel. In other examples, the third substrate core 232 can have a different internal arrangement of the TGVs 222A, 222B and the thin film capacitors 214A, 214B, 214C (e.g., some or all of the thin film capacitors 214A, 214B, 214C can be arranged in parallel, etc.).

In the illustrated example of FIG. 2C, the thin film capacitors 214B, 214C are similar to the first thin film capacitor 214A. In other examples, the thin film capacitor 214B, 214C can have a different size, shape, and/or configuration than the first thin film capacitor 214A. In the illustrated example of FIG. 2C, the thin film capacitor 214B, 214C are suspended in the middle of the third redistribution layer 210C and the fifth redistribution layer 210E, respectively. In other examples, one or both of the thin film capacitor 214B, 214C can abut a corresponding one of the glass cores 204, 206, and/or the adhesive dielectric 208. Additionally or alternatively, the third substrate core 232 can include one or more thin film capacitors disposed in some or all of the redistribution layers 210B, 210D, 210F. In the illustrated example of FIG. 2C, the thin film capacitors 214A, 214B, 214C are disposed in series. In other examples, the thin film capacitors 214A, 214B, 214C can be arranged in parallel and/or any other suitable configuration.

FIG. 2D illustrates an example fourth substrate core 234 that may be used to implement the example substrate core 128 of FIG. 1. In the illustrated example of FIG. 2D, the fourth substrate core 234 includes the glass cores 202, 204, 206 of FIGS. 2A-2C, the adhesive dielectric 208 of FIGS. 2A-2C, the first redistribution layer 210A of FIGS. 2A-2C, the second redistribution layer 210B of FIGS. 2A-2C, the outer surfaces 211, 212 of FIGS. 2A-2C, the first thin film capacitor 214A of FIGS. 2A-2C, the first TGVs 222A of FIGS. 2A-2C, the second TGVs 222B of FIG. 2C, the additional conductive material 224 of FIG. 2A, the conductive pads 226, 233A, 233B of FIG. 2C. The fourth substrate core 234 of FIG. 2D is similar to the third substrate core 232 of FIG. 2C, except that the fourth substrate core 234 does not include the third redistribution layer 210C of FIG. 2A, the fourth redistribution layer 210D of FIG. 2A, the fifth redistribution layer 210E of FIG. 2A, and the sixth redistribution layer 210F of FIG. 2A. Additionally, the fourth substrate core 234 includes an example fourth thin film capacitor 236A and an example fifth thin film capacitor 236B.

The fourth thin film capacitor 236A and the fifth thin film capacitor 236B are similar to the first thin film capacitor 214A, except as noted otherwise. In the illustrated example of FIG. 2D, the fourth thin film capacitor 236A and the fifth thin film capacitor 236B have greater footprints (e.g., lateral dimensions, etc.) than the first thin film capacitor 214A to facilitate the vertical coupling of the thin film capacitors 236A, 236B to the pads 233A, 233B (e.g., without redistribution in redistribution layers, etc.). In other examples, the fourth thin film capacitor 236A and the fifth thin film capacitor 236B can have a same footprint as the first thin film capacitor 214A. In the illustrated example of FIG. 2D, the fourth thin film capacitor 236A is disposed in the dielectric material (e.g., the adhesive dielectric 208, etc.) between the first glass core 202 and the 204 and directly abuts the second glass core 204. In the illustrated example of FIG. 2D, the fifth thin film capacitor 236B is disposed in the dielectric material (e.g., the adhesive dielectric 208, etc.) between the second glass core 204 and the third glass core 206 and directly abuts the third glass core 206.

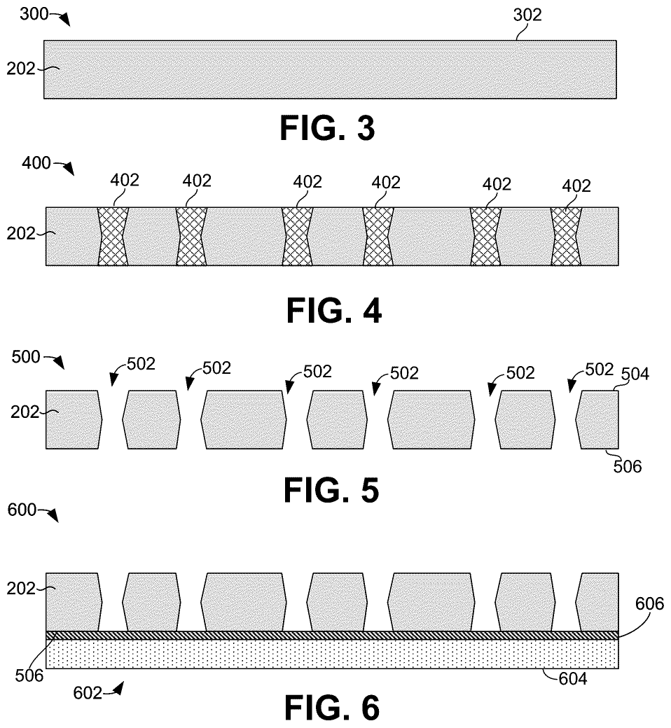

FIGS. 3-12 illustrate different stages in an example fabrication process to manufacture a glass core subassembly that can be used with the example first substrate core 200 of FIG. 2A, the example second substrate core 230 of FIG. 2B, the example third substrate core 232 of FIG. 2C, and/or the example fourth substrate core 234 of FIG. 2D. As used herein, the term “glass core subassembly” refers to a glass core of a substrate core including a stack of glass cores and any associated components that are embedded therein or disposed thereon (e.g., TGVs, thin film capacitors, redistribution layers, etc.)

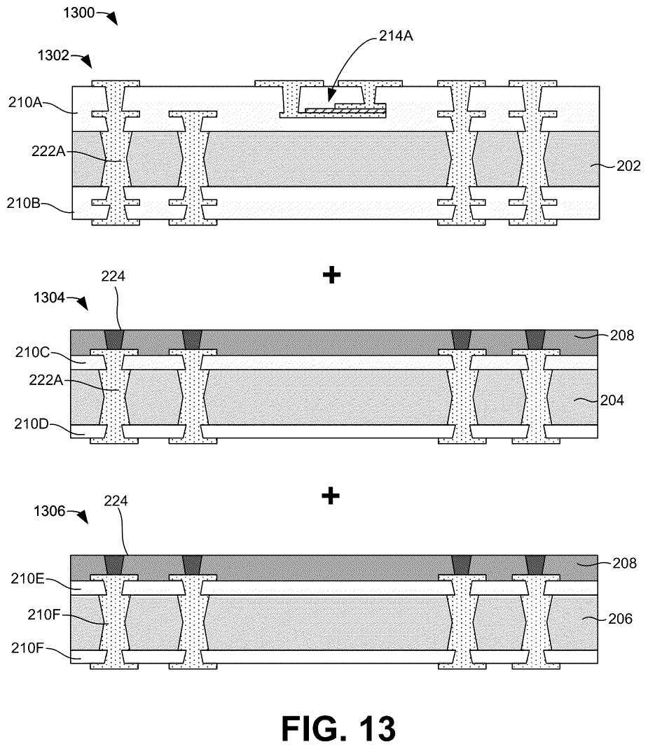

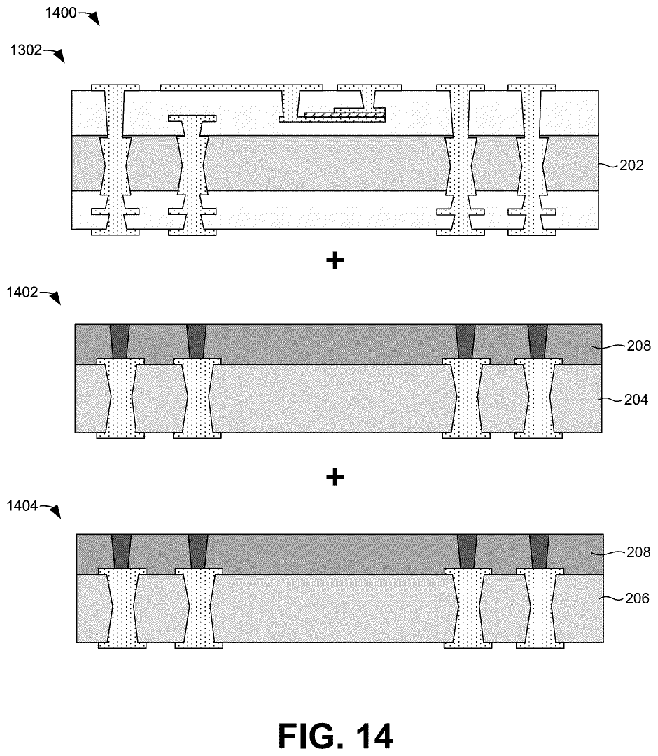

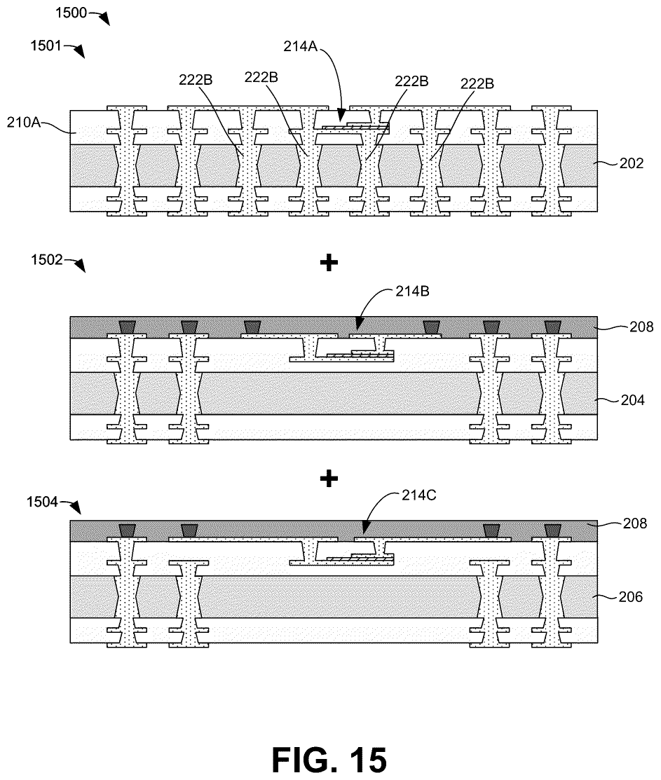

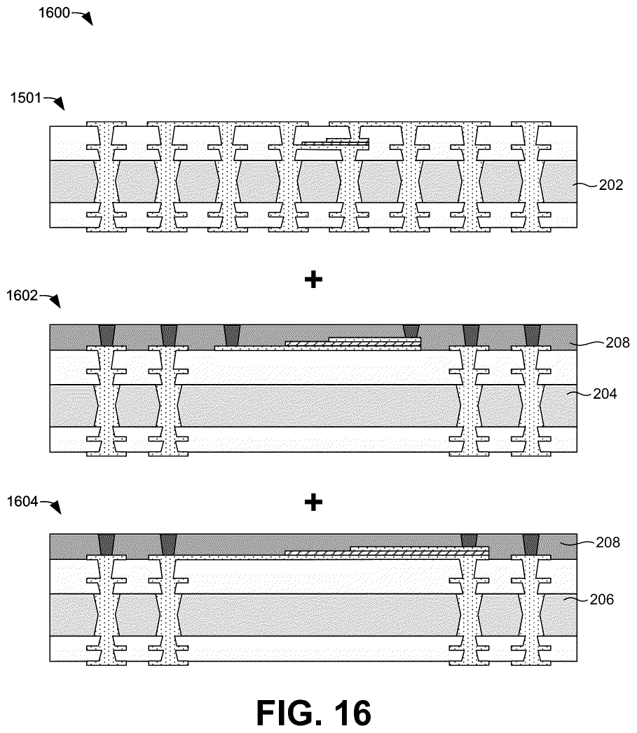

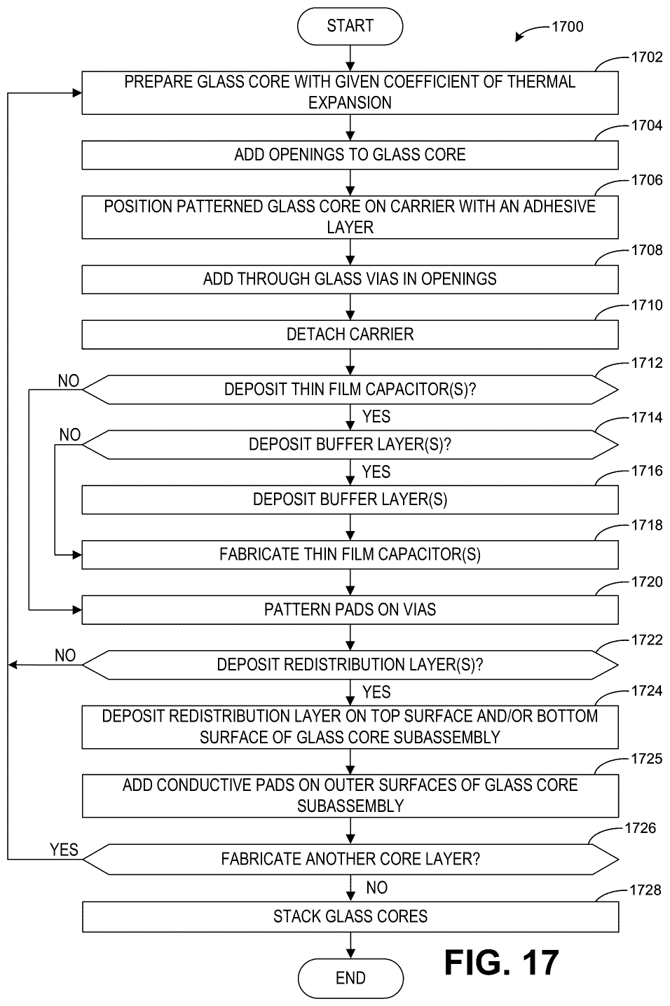

FIG. 13 illustrates an intermediate stage in another example fabrication process to manufacture the first substrate core 200 of FIG. 2A that can follow the different intermediate stages of FIGS. 3-12. FIG. 14 illustrates an intermediate stage in another example fabrication process to manufacture the second substrate core 230 of FIG. 2B that can follow the different intermediate stages of FIGS. 3-12. FIG. 15 illustrates an intermediate stage in another example fabrication process to manufacture the third substrate core 232 of FIG. 2C that can follow the different intermediate stages of FIGS. 3-12. FIG. 16 illustrates an intermediate stage in another example fabrication process to manufacture the fourth substrate core 234 of FIG. 2D that can follow the different intermediate stages of FIGS. 3-12. It should be appreciated that other processes and/or intermediate stages can be used to manufacture the example first substrate core 200 of FIG. 2A, the example second substrate core 230 of FIG. 2B, the example third substrate core 232 of FIG. 2C, and/or the example fourth substrate core 234 of FIG. 2D. Example operations to manufacture the substrate cores 200, 230, 232, 234 of FIGS. 2A-2D via some or all of the intermediate stages of FIGS. 3-16 are described below in conjunction with FIG. 17.

FIG. 3 is a cross-sectional schematic view of an example first intermediate stage 300 of the assembly/manufacturing of a glass core subassembly associated with the substrate cores 200, 230, 232, 234 of FIGS. 2A-2D. During the first intermediate stage 300, an example glass panel 302 is provided. The glass panel 302 can correspond to the initial state of any one of the glass cores 202, 204, 206. For purposes of explanation, the glass panel 302 is shown and described as corresponding to the first glass core 202 (e.g., the uppermost glass core in the substrate cores 200, 230, 232, 234 of FIGS. 2A-2D). In some examples, the glass panel 302 is fabricated to a thickness corresponding to the final thickness of the glass core 204. However, in some examples, the glass panel 302 is initially slightly larger than the final thickness of the first glass core 202 to enable some amount of the glass to be removed during subsequent polishing or planarization processes as discussed further below.

FIGS. 4-8 describe the formation of through glass vias (TGVs) in the glass core 202. The intermediate stages depicted in FIGS. 4-8 illustrate the formation of TGVs on the lateral sides of the first glass core 202 (e.g., the first TGVs 222A of FIGS. 2A-2D, etc.) and the center of the first glass core 202 (e.g., the second TGVs 222B of FIGS. 2C and 2D, etc.). If the first substrate core 200 of FIG. 2A and/or the second substrate core 230 of FIG. 2B are to be fabricated, the processing of the center of the glass core can be omitted during the intermediate stages depicted in FIGS. 3-8. Additionally or alternatively, the first TGVs 222A can created at another location in the glass core 202 (e.g., in the center of the first glass core 202, etc.), depending on the planned location of the thin film capacitors to be mounted on the glass core 202.

FIG. 4 is a cross-sectional schematic view of an example second intermediate stage 400 of the assembly/manufacturing of a glass core subassembly associated with the substrate cores 200, 230, 232, 234 of FIGS. 2A-2D. In some examples, the second intermediate stage 400 can occur after the first intermediate stage 300 of FIG. 3. During the second intermediate stage 400, the first glass core 202 is exposed to a laser as part of a laser induced deep etching (LIDE) process. The laser is concentrated on defined regions 402 of the glass core 204 to modify the optical and chemical properties of the glass core 204 at those regions 402.

FIG. 5 is a cross-sectional schematic view of an example third intermediate stage 500 of the assembly/manufacturing of a glass core subassembly associated with the substrate cores 200, 230, 232, 234 of FIGS. 2A-2D. In some examples, the third intermediate stage 500 can occur after the second intermediate stage 400 of FIG. 4. During the third intermediate stage 500, the first glass core 202 is exposed to a chemical etch process to remove the material in the modified regions 402 of the glass core 204 shown in FIG. 3 to define example openings 502 for the TGVs 222A, 222B shown in FIGS. 2A-2D. In the illustrated example of FIG. 5, the openings 502 have a cross-sectional profile generally corresponding to an hourglass shape with the width (e.g., diameter) of the openings 502 being narrower near a midpoint of the openings between opposing first surface 504 and second surface 506 of the glass core 204. In other examples, one or more of the openings 502 may have a different cross-sectional shape. For instance, in some examples, one or more of the openings 502 may have a generally conical or tapered shape with the width (e.g., diameter) being smallest at one of the two surfaces 504, 506 of the first glass core 202 and the width (e.g., diameter) being largest at the surface 504, 506. In other examples, the width (e.g., diameter) of one or more of the openings 502 is approximately consistent along a full length of the openings 502 between the opposing surfaces 504, 506 of the first glass core 202.

FIG. 6 is a cross-sectional schematic view of an example fourth intermediate stage 600 of the assembly/manufacturing of a glass core subassembly associated with the substrate cores 200, 230, 232, 234 of FIGS. 2A-2D. In some examples, the fourth intermediate stage 600 can occur after the third intermediate stage 500 of FIG. 5. During the fourth intermediate stage 600, an example conductive carrier 602 is attached to the second surface 506. In the illustrated example of FIG. 6, the conductive carrier includes a conductive layer 604 (e.g., a copper layer) and a release layer 606 (e.g., an adhesive dielectric layer).

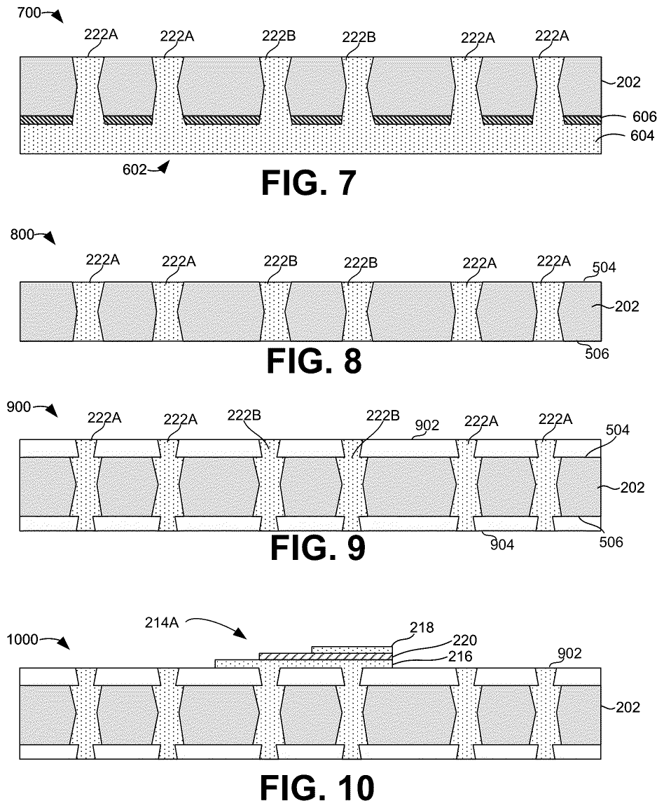

FIG. 7 is a cross-sectional schematic view of an example fifth intermediate stage 700 of the assembly/manufacturing of a glass core subassembly associated with the substrate cores 200, 230, 232, 234 of FIGS. 2A-2D. In some examples, the fifth intermediate stage 700 can occur after the fourth intermediate stage 600 of FIG. 6. During the fifth intermediate stage 700, a conductive material (e.g., copper, etc.) is deposited (e.g., plated, etc.) within the openings 502 to define the TGVs 222A, 222B extending through the first glass core 202. In this example, the TGVs 222A, 222B are plated up from the exposed portions of the conductive layer 604. As such, in this example, there is no seed layer deposited along the walls of the openings 502 prior to the plating process. However, in other examples, a seed layer may be used to facilitate the plating of the TGVs 222A, 222B.

In some examples, the fifth intermediate stage 700 occurs after an etching process (e.g., a plasma etch, a dry etch) to remove portions of the release layer 606 exposed within the openings 502 of the glass core 204, thereby exposing the underlying conductive layer 604. In some examples, after the fifth intermediate stage 700, the first surface 504 of the first glass core 202 is polished (e.g., via a chemical mechanical planarization (CMP) process, etc.) to remove excess copper that extends above the first surface 504 of the glass core 204. Thus, in some examples, the TGVs 222A, 222B are flush with the first surface 504.

FIG. 8 is a cross-sectional schematic view of an example sixth intermediate stage 800 of the assembly/manufacturing of a glass core subassembly associated with the substrate cores 200, 230, 232, 234 of FIGS. 2A-2D. In some examples, the sixth intermediate stage 800 can occur after the fifth intermediate stage 700 of FIG. 7. During the sixth intermediate stage 800, the conductive carrier 602, including both the conductive layer 604 and the release layer 606 is removed. In some examples, the second surface 506 of the glass core undergoes a polishing process (e.g., a CMP process, etc.) to make the TGVs 222A, 222B flush with the second surface 506. In some examples, the first glass core 202 also undergoes a cleaning process to remove any residue materials.

FIG. 9 is a cross-sectional schematic view of an example seventh intermediate stage 900 of the assembly/manufacturing of a glass core subassembly associated with the substrate cores 200, 230, 232, 234 of FIGS. 2A-2D. In some examples, the seventh intermediate stage 900 can occur after the sixth intermediate stage 800 of FIG. 8. During the seventh intermediate stage 900, an example first layer 902 and an example second layer 904 have been deposited on the first surface 504 and the second surface 506 of the first glass core 202, respectively. The layers 902, 904 include (e.g., are composed of, etc.) a dielectric material, such as ABF. In some examples, the first layer 902 and the second layer 904 are deposited via lamination and/or another thin film deposition (TFD) technique. In other examples, the first layer 902 and the second layer 904 can be deposited via any other suitable process. In some examples, the layers 902, 904 correspond to portions of the redistribution layers 210A, 210B of FIGS. 2A-2D, respectively. In the illustrated example, the layers 902, 904 have been patterned such that the TGVs 222A, 222B extend through the layers 902, 904. For example, the layers 902, 904 can be drilled to create openings aligned with the TGVs 222A, 222B, and conductive material can be disposed in the created openings. In some examples, the steps of the fabrication process associated with the seventh intermediate stage 900 of FIG. 9 can be omitted (e.g., if the second glass core 204 and the third glass core 206 are being fabricated to have the configuration of FIG. 2B or FIG. 2D, etc.). In some such examples, the layers 902, 904 can be polished such that the TGVs 222A, 222B are flush therewith.

FIG. 10 is a cross-sectional schematic view of an example eighth intermediate stage 1000 of the assembly/manufacturing of a glass core subassembly associated with the substrate cores 200, 230, 232, 234 of FIGS. 2A-2D. In some examples, the eighth intermediate stage 1000 can occur after the seventh intermediate stage 900 of FIG. 9. During the eighth intermediate stage 1000, the thin film capacitor 214A is disposed on the first redistribution layer 210A. In some examples, the thin film capacitor 214A is fabricated on the first layer 902. In some such examples, the bottom electrode layer 216, the dielectric layer 220, and the top electrode layer 218 are deposited sequentially on the redistribution layer 210A (e.g., the bottom electrode layer 216 is deposited on the first layer 902, the dielectric layer 220 is deposited on the bottom electrode layer 216, the top electrode layer 218 is deposited on the dielectric layer 220, etc.). In some such examples, the electrode layers 216, 218 are deposited via electroplating. In some such examples, seed layer(s) (not illustrated) are deposited on the first layer 902 and/or the dielectric layer 220 prior to the plating of the corresponding ones of the electrode layers 216, 218. In other examples, the bottom electrode layer 216 and/or the top electrode layer 218 are deposited via another method(s) (e.g., chemical vapor deposition (CVD), atomic layer deposition (ALD), lamination, lithography, etc.). The dielectric layer 220 can be deposited via lamination and/or TFD. In other examples, the thin film capacitor 214A is fabricated separately and mechanically deposited on the first redistribution layer 210A (e.g., via pick and place, etc.).

In the illustrated example of FIG. 10, the thin film capacitor 214A is positioned such that the bottom electrode layer 216 abuts (e.g., is in contact with, etc.) the second TGVs 222B. In other examples, the thin film capacitor 214A can have any other suitable position on the first layer 902. Additionally or alternatively, a thin film capacitor of a different size can be deposited on the first layer 902 (e.g., the fourth thin film capacitor of FIG. 2D, the fifth thin film capacitor 236B of FIG. 2D, a smaller thin film capacitor, etc.). While the illustrated example of FIG. 9 depicts the deposition of a single thin film capacitor (e.g., the thin film capacitor 214A, etc.) on the first layer, it should be appreciated that additional thin film capacitors can be deposited on the first layer 902. Additionally, in some examples, the eighth intermediate stage 1000 can be omitted to fabricate a glass core without a thin film capacitor disposed thereon.

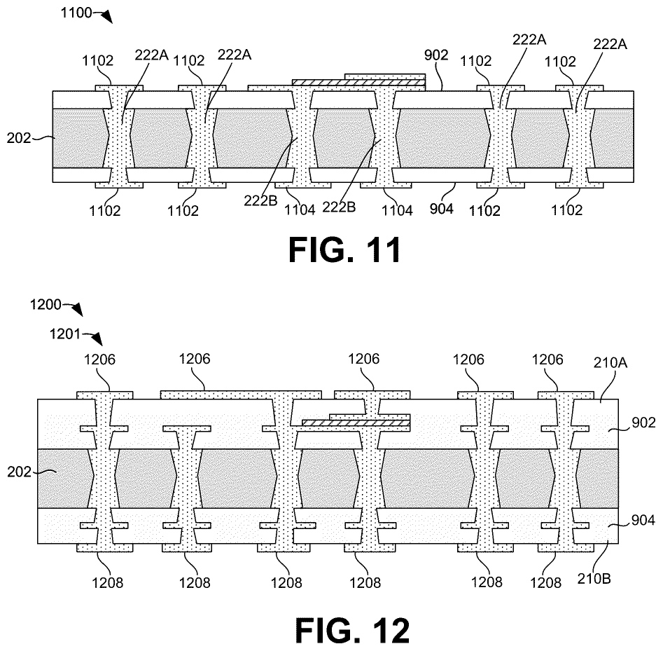

FIG. 11 is a cross-sectional schematic view of an example ninth intermediate stage 1100 of the assembly/manufacturing of a glass core subassembly associated with the substrate cores 200, 230, 232, 234 of FIGS. 2A-2D. In some examples, the ninth intermediate stage 1100 can occur after the eighth intermediate stage 1000 of FIG. 10. During the ninth intermediate stage 1100, example first pads 1102 and example second pads 1104 are patterned on the first layer 902 and the second layer 904. In the illustrated example of FIG. 11, the first pads 1102 are patterned on the first layer 902 to be aligned with the TGVs 222A, 222B and the second pads 1104 are patterned on the second layer 904 to be aligned with the TGVs 222A, 222B. In some examples, if the intermediate stage 1000 of FIG. 10 were omitted, the first pads 1102 are also patterned on the second TGVs 222B. In some examples, the pads 1102, 1104 are deposited via lithography. Additionally or alternatively, the pads 1102, 1104 can be deposited via another suitable process (e.g., ALD, CVD, electroplating, etc.) or a combination thereof. In the illustrated example of FIG. 10, the first pads 1102 are associated with the interconnections of the first redistribution layer 210A and the second pads 1104 are associated with the interconnections of the second redistribution layer 210B.

FIG. 12 is a cross-sectional schematic view of an example tenth intermediate stage 1200 of the assembly/manufacturing of a glass core subassembly associated with the substrate cores 200, 230, 232, 234 of FIGS. 2A-2D. In some examples, the tenth intermediate stage 1200 can occur after the ninth intermediate stage 1100 of FIG. 11. During the tenth intermediate stage 1200, the first redistribution layer 210A and the second redistribution layer 210B are fabricated on the first layer 902 and the second layer 904, respectively to form an example glass core subassembly 1201. The redistribution layers 210A, 210B and the interconnections disposed therein can be fabricated via a plurality of fabrication steps (e.g., electroplating of interconnections, lamination of the dielectric associated with the redistribution layers, etc.). In the illustrated example of FIG. 12, the first redistribution layer 210A is disposed around the thin film capacitor 214A (e.g., the thin film capacitor 214A is encompassed by the first redistribution layer 210A. In other examples, the deposition of one or both of the redistribution layers 210A, 210B are omitted. In the illustrated example of FIG. 12, example first conductive pads 1206 are patterned on the first redistribution layer 210A and example second conductive pads 1208 are patterned on the second redistribution layer 210B. The pads 1206, 1208 are coupled to the TGVs 222A, 222B and electrically couple the glass core subassembly 1201 to external structures (e.g., the dies 106, 108 of FIG. 1, etc.) and/or adjacent glass core subassemblies. In the illustrated example of FIG. 12, the first conductive pads 1206 correspond to ones of the conductive pads 226, 228 of FIGS. 2A-2D.

FIG. 13 is a cross-sectional schematic view of an example eleventh intermediate stage 1300 of the assembly/manufacturing of the first substrate core 200 of FIG. 2A. In some examples, the eleventh intermediate stage 1300 can occur after the fabrication of an example first glass core subassembly 1302, an example second glass core subassembly 1304, and an example third glass core subassembly 1306. In the illustrated example of FIG. 13, the first glass core subassembly 1302, the second glass core subassembly 1304, and the third glass core subassembly 1306 include the first glass core 202 of FIG. 2A, the second glass core 204 of FIG. 2A, and the third glass core 206 of FIG. 2A, respectively. In some examples, each of the glass core subassemblies 1302, 1304, 1306 can be manufactured via some or all the intermediate stages 300, 400, 500, 600, 700, 800, 900, 1000, 1100, 1200 of FIGS. 3-12. For example, the first glass core subassembly 1302 can be manufactured via each of the intermediate stages 300, 400, 500, 600, 700, 800, 900, 1000, 1100, 1200 of FIGS. 3-12. That is, the first glass core subassembly 1302 corresponds to the glass core subassembly 1201 of FIG. 12, except that the first glass core subassembly 1302 does not include the second TGVs 222B.

The second glass core subassembly 1304 and the third glass core subassembly 1306 can be manufactured can be manufactured via the intermediate stages 300, 400, 500, 600, 700, 800, 900, 1100 of FIGS. 3-9, and 11, and 12 (e.g., the deposition of a thin film capacitor, such as the thin film capacitor 214A, during the intermediate stage 1000 of FIG. 10 is omitted). In other examples, the glass core subassemblies 1302, 1304, 1306 of FIG. 13 can be manufactured via any other suitable process. In the illustrated example of FIG. 13, the redistribution layers 210C, 210D, 210E, 210F include direct connections between vertically aligned ones of the TGVs 222A. In other examples, the redistribution layers 210C, 210D, 210E, 210F can include additional interconnections, which can extend between non-vertically adjacent ones of the TGVs 222A.

During the eleventh intermediate stage 1300, the three glass cores 202, 204, 206 are assembled or stacked together by combining or joining the glass core subassemblies 1302, 1304, 1306. In some examples, an adhesive resin is used on the interfacing surfaces of the glass core subassemblies 1302, 1304, 1306 to join them together. More particularly, in the illustrated example of FIG. 13, the adhesive resin is the adhesive dielectric 208 of FIGS. 2A-2D, which is applied to the regions of the dielectric material on the interfacing surfaces of the glass core subassemblies 1302, 1304, 1306. In the illustrated example of FIG. 13, the additional conductive material 224 (e.g., a liquid metal, copper paste, etc.) is deposited between portions of the interfacing surfaces defined by conductive material to electrically couple the conductive material in the stack (e.g., the TGVs 222A, 222B, the interconnections of the redistribution layers 210A, 210B, 210C, 210D, 210E, 210F, pads patterned on the redistribution layers 210A, 210B, 210C, 210D, 210E, 210F, etc.). In other examples, no additional material is added between the interfacing surfaces of the glass core subassemblies 1302, 1304, 1306. Instead, the material on the interfacing surfaces is directly joined (e.g., with fusion bonds, etc.). The result of combining or joining the glass core subassemblies 1302, 1304, 1306 produces the first substrate core 200 of FIG. 2A.

FIG. 14 is a cross-sectional schematic view of an example twelfth intermediate stage 1400 associated with the assembly/manufacturing of the second substrate core 230 of FIG. 2B. In some examples, the twelfth intermediate stage 1400 can occur after the fabrication of the first glass core subassembly 1302 of FIG. 13, an example fourth glass core subassembly 1402, and an example fifth glass core subassembly 1404. In the illustrated example of FIG. 14, the fourth glass core subassembly 1402 and the fifth glass core subassembly 1404 include the second glass core 204 of FIG. 2B, and the third glass core 206 of FIG. 2B, respectively. The fourth glass core subassembly 1402 and the fifth glass core subassembly 1404 can be manufactured via the intermediate stages can be manufactured via the intermediate stages 300, 400, 500, 600, 700, 800, 1100 of FIGS. 3-8 and 11 (e.g., the deposition of a thin film capacitor during the intermediate stage 1000 of FIG. 10 and the deposition of redistribution layers during the intermediate stages 900, 1100, 1200 of FIGS. 9, 11, and 12 are omitted, etc.). In other examples, the glass core subassemblies 1302, 1402, 1404 of FIG. 14 can be manufactured via any other suitable process.

During the twelfth intermediate stage 1400, the three glass cores 202, 204, 206 are assembled or stacked together by combining or joining the glass core subassemblies 1302, 1402, 1404. The glass core subassemblies 1302, 1402, 1404 of FIG. 14 can be stacked/assembled in a manner similar to the stacking of the glass core subassemblies 1302, 1304, 1306 of FIG. 13 described in conjunction with FIG. 13. The result of combining or joining the glass core subassemblies 1302, 1402, 1404 produces the second substrate core 230 of FIG. 2B.

FIG. 15 is a cross-sectional schematic view of an example thirteenth intermediate stage 1500 associated with the assembly/manufacturing of the third substrate core 232 of FIG. 2C. In some examples, the thirteenth intermediate stage 1500 can occur after the fabrication of an example sixth glass core subassembly 1501, an example seventh glass core subassembly 1502, and an example eighth glass core subassembly 1504. In the illustrated example of FIG. 15, the seventh glass core subassembly 1502 and the eighth glass core subassembly 1504 include the second glass core 204 of FIGS. 2C, and the third glass core 206 of FIGS. 2C, respectively. The sixth glass core subassembly 1501 is similar to the first glass core subassembly 1302, except that the sixth glass core subassembly 1501 includes the second TGVs 222B and a different configuration of pads on the first redistribution layer 210A to accommodate electrical connections to the thin film capacitors 214A, 214B, 214C (e.g., the sixth glass core subassembly 1501 includes the pads 233A, 233B, etc.).

The sixth glass core subassembly 1501, the seventh glass core subassembly 1502 and the eighth glass core subassembly 1504 can be manufactured via each of the intermediate stages 300, 400, 500, 600, 700, 800, 900, 1000, 1100, 1200 of FIGS. 3-12. In other examples, the glass core subassemblies 1501, 1502, 1504 of FIG. 15 can be manufactured via any other suitable process. During the thirteenth intermediate stage 1500, the three glass cores 202, 204, 206 are assembled or stacked together by combining or joining the glass core subassemblies 1201, 1502, 1504. The glass core subassemblies 1501, 1502, 1504 of FIG. 15 can be stacked/assembled in a manner similar to the stacking of the glass core subassemblies 1302, 1304, 1306 of FIG. 13 described in conjunction with FIG. 13. The result of combining or joining the glass core subassemblies 1501, 1502, 1504 produces the substrate core 232 of FIG. 2C.

FIG. 16 is a cross-sectional schematic view of an example fourteenth intermediate stage 1600 associated with the assembly/manufacturing of the fourth substrate core 234 of FIG. 2D. In some examples, the fourteenth intermediate stage 1600 can occur after the fabrication of the sixth glass core subassembly 1501, an example ninth glass core subassembly 1602, and an example tenth glass core subassembly 1604. In the illustrated example of FIG. 16, the ninth glass core subassembly 1602 includes the second glass core 204 of FIG. 2D and the fourth thin film capacitor 236A of FIG. 2D. In the illustrated example of FIG. 16, the tenth glass core subassembly 1604 includes the third glass core 206 of FIG. 2D and the fifth thin film capacitor 236B. The ninth glass core subassembly 1602 and the tenth glass core subassembly 1604 can be manufactured via the intermediate stages 300, 400, 500, 600, 700, 800, 1000, 1200 of FIGS. 3-8, 10, and 11 (e.g., the deposition of redistribution layers during the intermediate stages 900, 1100, 1200 of FIGS. 9, and 12 are omitted, etc.). In other examples, the glass core subassemblies 1302, 1602, 1604 of FIG. 16 can be manufactured via any other suitable process. During the fourteenth intermediate stage 1600, the three glass cores 202, 204, 206 are assembled or stacked together by combining or joining the glass core subassemblies 1501, 1602, 1604. The glass core subassemblies 1501, 1602, 1604 of FIG. 16 can be stacked/assembled in a manner similar to the stacking of the glass core subassemblies 1302, 1304, 1306 of FIG. 13 described in conjunction with FIG. 13. The result of combining or joining the glass core subassemblies 1501, 1602, 1604 produces the fourth substrate core 234 of FIG. 2D.

FIG. 17 is a flowchart representative of an example method that may be performed to fabricate any one of the example substrate cores 200, 230, 232, 234 of FIGS. 2A-2D via the intermediate stages 300, 400, 500, 600, 700, 800, 900, 1000, 1100, 1200, 1300, 1400, 1500, 1600 of FIGS. 3-16. In some examples, some or all of the operations outlined in the example method of FIG. 17 are performed automatically by equipment that is programmed to perform the operations. Although the example method is described with reference to the flowchart illustrated in FIG. 17, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method of FIG. 17 begins at block 1702 by preparing a glass core (e.g., any one of the glass cores 202, 204, 206) with a given coefficient of thermal expansion (CTE). For example, the coefficients of thermal expansion of each of the glass cores 202, 204, 206 can be tuned by tailoring (e.g., varying, changing, etc.) the composition of the glass of each of the layers. For example, the coefficients of thermal expansion of each of the glass cores 202, 204, 206 can be tailored by varying the relative proportions of Al₂O₃, B₂O₃, Li₂O, Na₂O, K₂O, Sb₂O₃, and/or other additives in each of the layers and/or via processing variations (e.g., lamination cladding, thermal treatment, etc.). In some examples, the composition of materials used in the glass core is selected to achieve the CTE intended for a particular layer of glass within an overall substrate core that includes multiple glass cores stacked together. The point of fabrication after completion of block 1702 corresponds to the structure of the first intermediate stage 300 of FIG. 3. At block 1704, the example method includes adding openings through the glass core. For example, openings corresponding to the first TGVs 222A and/or the second TGVs 222B can be formed in the glass core 202. For example, the openings can be formed via laser exposure and/or etching. The point of fabrication after completion of block 1704 corresponds to the structure of the second intermediate stage 400 of FIG. 4.

At block 1706, the example method involves attaching a carrier to the glass core 202. For example, the glass core 202 can be attached to the conductive carrier 602 of FIG. 6 via the adhesive layer 606. The point of fabrication after completion of block 1706 corresponds to the structure of the fourth intermediate stage 600 of FIG. 6. At block 1708, the example method involves depositing conductive material into the openings to define TGVs (e.g., the first TGVs 222A and/or the second TG) through the glass core. For example, the TGVs 222A, 222B can be formed in the openings via electroplating from a conductive layer of the attached carrier (e.g., fully bottom-up plating, partially bottom-up plating, etc.). The point of fabrication after completion of block 1708 corresponds to the structure of the fifth intermediate stage 700 of FIG. 7. At block 1710, the example method involves the detachment of the conductive carrier 602 from the glass core 202. In some examples, the glass core 202 is polished and cleaned after the detachment of the conductive carrier 602. The point of fabrication after completion of block 1710 corresponds to the structure of the sixth intermediate stage 800 of FIG. 8.

At block 1712, the method includes determining if one or more thin film capacitor(s) (e.g., one of the thin film capacitors 214A, 214B, 214C, 236A, 236B etc.) are to be deposited on the glass core 202. If a thin film capacitor is to be deposited on the glass core 202, the method advances to block 1714. If a thin film capacitor is not to be deposited on the glass core 202, the method advances to block 1720. At block 1714, the method includes determining if one or more buffer layer(s) (e.g., the layers 902, 904, etc.) are to be deposited on the glass core 202. If a buffer layer is to be deposited on the glass core 202, the method advances to block 1716. If a buffer layer is not to be deposited on the glass core 202, the method advances to block 1718.

At block 1716, one or more layer(s) are deposited on the glass core 202. For example, one or both of the layers 902, 904 of FIG. 9 can be deposited on the top surface of glass core 202 and/or the bottom surface of glass core 202, respectively. In some examples, the first layer 902 and the second layer 904 are deposited via lamination and/or another thin film deposition (TFD) method. In other examples, the first layer 902 and the second layer 904 can be deposited via any other suitable process. In some examples, the layers 902, 904 can be processed (e.g., drilled, patterned via lithography, etc.) to form openings aligned with the TGVs 222A, 222B. In some such examples, conductive material can be disposed therein to extend the TGVs to the outer surfaces of the layers 902, 904. The point of fabrication after completion of block 1716 corresponds to the structure of the seventh intermediate stage 900 of FIG. 9.

At block 1718, one or more thin film capacitors are fabricated. For example, the first thin film capacitor 214A can be deposited on the layer 902 (e.g., if the layer 902 is deposited on the first glass core 202, etc.) and/or directly on the glass core (e.g., if the layer 902 was not deposited on the first glass core 202). In some examples, the thin film capacitor 214A is fabricated on the first layer 902. In some such examples, the bottom electrode layer 216, the dielectric layer 220, and the top electrode layer 218 are deposited sequentially on the redistribution layer 210A (e.g., the bottom electrode layer 216 is deposited on the first layer 902, the dielectric layer 220 is deposited on the bottom electrode layer 216, the top electrode layer 218 is deposited on the dielectric layer 220, etc.). In some such examples, the electrode layers 216, 218 are deposited via electroplating. In some such examples, seed layer(s) (not illustrated) are deposited on the first layer 902 and/or dielectric layer 220 prior to the plating of the corresponding ones of the electrode layers 216, 218. In other examples, the bottom electrode layer 216 and/or the top electrode layer 218 are deposited via another method (e.g., CVD, ALD, lamination, etc.). The dielectric layer 220 can be deposited via lamination and/or TFD. In other examples, the thin film capacitor 214A can be fabricated separately and mechanically deposited on the first redistribution layer 210A (e.g., via pick and place, etc.). The point of fabrication after completion of block 1716 corresponds to the structure of the eighth intermediate stage 1000 of FIG. 10.

At block 1720, the example method involves the patterning of pads on the exposed ones of the TGVs 222A, 222B. For example, the first pads 1102 of FIG. 11 can be patterned on the first layer 902 to be aligned with the TGVs 222A, 222B and the second pads 1104 of FIG. 11 can be patterned on the second layer 904 to be aligned with the TGVs 222A, 222B. In some examples, the pads 1102, 1104 are deposited via lithography. Additionally or alternatively, the pads 1102, 1104 can be deposited via another suitable process (e.g., ALD, CVD, electroplating, etc.) or a combination thereof. The point of fabrication after completion of block 1716 corresponds to the structure of the ninth intermediate stage 1100 of FIG. 11.

At block 1722, the example method includes determining if one or more redistribution layers (e.g., one of the redistribution layer 210A, 210B, 210C, 210D, 210E, 210F, etc.) is to be deposited on the glass core 202. If one or more redistribution layer(s) is to be deposited on the glass core 202, the method advances to block 1724. If one or more redistribution layer(s) is not to be deposited on the glass core 202, the method advances to block 1725. At block 1724, the example method involves depositing redistribution layer(s) on the top surface and/or bottom surface of the glass core 202. For example, the materials for additional redistribution layer(s) (e.g., the dielectric layers, interconnections, etc.) can be deposited on the glass core 202 and/or the layers 902, 904.

At block 1725, the example method involves adding conductive pads (e.g., the conductive pads 1206, 1208 of FIG. 12) on the outer surfaces of the glass core subassembly. In some examples, conductive pads are added to only one of the two surfaces (e.g., one of the top surface or the bottom surface, etc.) In some examples, the conductive pads are added to both surfaces. In some examples, whether conductive pads are added to both, one, or neither outer surface of the glass core depends on where the glass core is to be located in the stack of glass cores and the manner in which the different glass cores are combined or joined in the stack. The point of fabrication after completion of block 1725 corresponds to the structure of the tenth intermediate stage 1200 of FIG. 12.

At block 1726, the example method involves determining whether to fabricate another glass core assembly (e.g., the glass core subassemblies 1302, 1304, 1306, 1402, 1404, 1502, 1504, 1602, 1604, etc.). If so, the process returns to block 1702 to repeat the process for a different glass core. In some examples, the different glass core can be constructed with a different CTE, include a different configuration of thin film capacitors and/or include a different configuration of redistribution layers. In some examples, the separate iterations through the example process can be performed in parallel rather than sequentially. Once there are no further glass core assemblies to fabricate, the example process advances to block 1728 that involves stacking (e.g., combining, etc.) the glass core assemblies. In some examples, the glass core assemblies, as completed up to block 1726, are directly joined together (as represented in FIGS. 13-16) to form a corresponding one of the substrate cores 200, 230, 232, 234 of FIGS. 2A-2D. In other examples, a dielectric adhesive (e.g., the adhesive dielectric 208 of FIGS. 2A-2D, etc.) may be added onto at least one side of the interfacing surfaces of adjacent glass core assemblies to facilitate the connecting of the glass core assemblies. In some such examples, additional conductive vias (e.g., the additional conductive material 224 of FIGS. 2A-2D, etc.) are provided to extend through the dielectric adhesive. The completion of the example process of FIG. 17 results in a completed substrate core (e.g., any one of the substrate cores 200, 230, 232, 234, etc.). Thereafter, the completed substrate core may undergo any suitable subsequent processing (e.g., adding build-up layers, attaching one or more dies, and implementing other packaging processes).

Although the example operations 1700 are described with reference to the flowchart illustrated in FIG. 17, many other methods of assembling/manufacturing the substrate cores 200, 230, 232, 234 of FIGS. 2A-2D may alternatively be used. For example, the order of execution of the blocks may be changed, and/or some of the blocks described may be changed, eliminated, or combined.

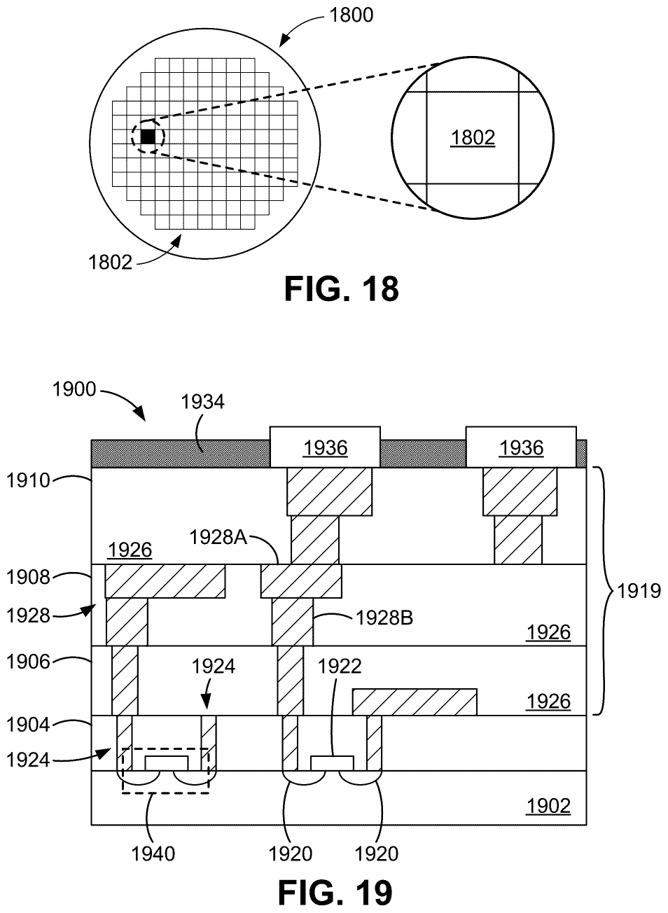

The example IC package 100 of FIG. 1 (e.g., with any of the example substrate cores 200, 230, 232, 234, etc.) disclosed herein may be included in any suitable electronic component. FIGS. 18-21 illustrate various examples of apparatus that may include or be included in the IC package 100 disclosed herein.

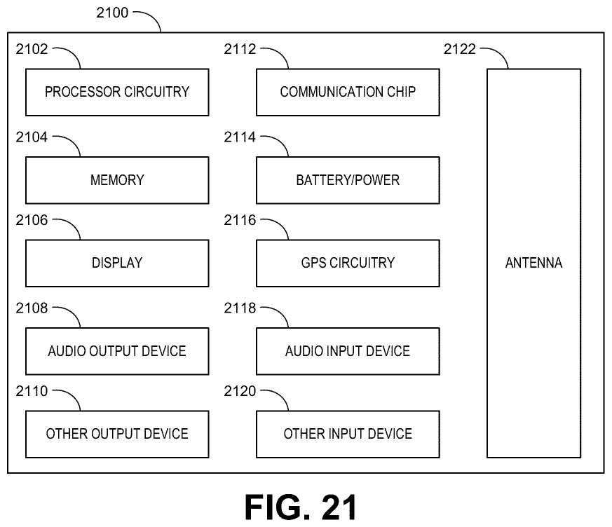

FIG. 18 is a top view of a wafer 1800 and dies 1802 that may be included in the IC package 100 of FIG. 1 (e.g., as any suitable ones of the dies 106, 108). The wafer 1800 includes semiconductor material and one or more dies 1802 having circuitry. Each of the dies 1802 may be a repeating unit of a semiconductor product. After the fabrication of the semiconductor product is complete, the wafer 1800 may undergo a singulation process in which the dies 1802 are separated from one another to provide discrete “chips.” The die 1802 includes one or more transistors (e.g., some of the transistors 1940 of FIG. 19, discussed below), supporting circuitry to route electrical signals to the transistors, passive components (e.g., traces, resistors, capacitors, inductors, and/or other circuitry), and/or any other components. In some examples, the die 1802 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die (e.g., the die 1802, etc.). For example, a memory array of multiple memory circuits may be formed on a same die (e.g., die 1802 as programmable circuitry (e.g., the processor circuitry 2102 of FIG. 21) and/or other logic circuitry. Such memory may store information for use by the programmable circuitry. The example IC package 100 disclosed herein may be manufactured using a die-to-wafer assembly technique in which some dies are attached to a wafer 1800 that includes others of the dies, and the wafer 1800 is subsequently singulated.

FIG. 19 is a cross-sectional side view of an IC device 2000 that may be included in the example IC package 100 (e.g., in any one of the dies 106, 108). One or more of the IC devices 1900 may be included in one or more dies 1802 (FIG. 18). The IC device 1900 may be formed on a die substrate 1902 (e.g., the wafer 1800 of FIG. 18) and may be included in a die (e.g., the die 1802 of FIG. 18). The die substrate 1902 may be a semiconductor substrate including semiconductor materials including, for example, n-type or p-type materials systems (or a combination of both). The die substrate 1902 may include, for example, a crystalline substrate formed using a bulk silicon or a silicon-on-insulator (SOI) substructure. In some examples, the die substrate 1902 may be formed using alternative materials, which may or may not be combined with silicon, which include but are not limited to germanium, indium antimonide, lead telluride, indium arsenide, indium phosphide, gallium arsenide, or gallium antimonide. Further materials classified as group II-VI, III-V, or IV may also be used to form the die substrate 1902. Although a few examples of materials from which the die substrate 1902 may be formed are described here, any material that may serve as a foundation for an IC device 1900 may be used. The die substrate 1902 may be part of a singulated die (e.g., the dies 1802 of FIG. 18) or a wafer (e.g., the wafer 1800 of FIG. 18).

The IC device 1900 may include one or more device layers 1904 disposed on and/or above the die substrate 1902. The device layer 1904 may include features of one or more transistors 1940 (e.g., metal oxide semiconductor field-effect transistors (MOSFETs)) formed on the die substrate 1902. The device layer 1904 may include, for example, one or more source and/or drain (S/D) regions 1920, a gate 1922 to control current flow between the S/D regions 1920, and one or more S/D contacts 1924 to route electrical signals to/from the S/D regions 1920. The transistors 1940 may include additional features not depicted for the sake of clarity, such as device isolation regions, gate contacts, and the like. The transistors 1940 are not limited to the type and configuration depicted in FIG. 19 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1940 may include a gate 1922 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1940 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 1940 along the source-channel-drain direction, the gate electrode may include a U-shaped structure that includes a bottom portion substantially parallel to the surface of the die substrate 1902 and two sidewall portions that are substantially perpendicular to the top surface of the die substrate 1902. In other examples, at least one of the metal layers that form the gate electrode may be a planar layer that is substantially parallel to the top surface of the die substrate 1902 and does not include sidewall portions substantially perpendicular to the top surface of the die substrate 1902. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 1920 may be formed within the die substrate 1902 adjacent to the gate 1922 of corresponding transistor(s) 1940. The S/D regions 1920 may be formed using an implantation/diffusion process or an etching/deposition process, for example. In the former process, dopants such as boron, aluminum, antimony, phosphorous, or arsenic may be ion-implanted into the die substrate 1902 to form the S/D regions 1920. An annealing process that activates the dopants and causes them to diffuse farther into the die substrate 1902 may follow the ion-implantation process. In the latter process, the die substrate 1902 may first be etched to form recesses at the locations of the S/D regions 1920. An epitaxial deposition process may then be carried out to fill the recesses with material that is used to fabricate the S/D regions 1920. In some implementations, the S/D regions 1920 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1920 may be formed using one or more alternate semiconductor materials such as germanium or a group III-V material or alloy. In further examples, one or more layers of metal and/or metal alloys may be used to form the S/D regions 1920.

Electrical signals, such as power and/or input/output (I/O) signals, may be routed to and/or from the devices (e.g., transistors 1940) of the device layer 1904 through one or more interconnect layers disposed on the device layer 1904 (illustrated in FIG. 19 as interconnect layers 1906-1910). For example, electrically conductive features of the device layer 1904 (e.g., the gate 1922 and the S/D contacts 1924) may be electrically coupled with the interconnect structures 1928 of the interconnect layers 1906-1910. The one or more interconnect layers 1906-1910 may form a metallization stack (also referred to as an “ILD stack”) 1919 of the IC device 1900.

The interconnect structures 1928 may be arranged within the interconnect layers 1906-1910 to route electrical signals according to a wide variety of designs (in particular, the arrangement is not limited to the particular configuration of interconnect structures 1928 depicted in FIG. 19). Although a particular number of interconnect layers 1906-1910 is depicted in FIG. 19, examples of the present disclosure include IC devices having more or fewer interconnect layers than depicted.

In some examples, the interconnect structures 1928 may include lines 1928A and/or vias 1928B filled with an electrically conductive material such as a metal. The lines 1928A may be arranged to route electrical signals in a direction of a plane that is substantially parallel with a surface of the die substrate 1902 upon which the device layer 1904 is formed. For example, the lines 1928A may route electrical signals in a direction in and/or out of the page from the perspective of FIG. 19. The vias 1928B may be arranged to route electrical signals in a direction of a plane that is substantially perpendicular to the surface of the die substrate 1902 upon which the device layer 1904 is formed. In some examples, the vias 1928B may electrically couple lines 1928A of different interconnect layers 1906-1910 together.

The interconnect layers 1906-1910 may include a dielectric material 1926 disposed between the interconnect structures 1928, as shown in FIG. 19. In some examples, the dielectric material 1926 disposed between the interconnect structures 1928 in different ones of the interconnect layers 1906-1910 may have different compositions; in other examples, the composition of the dielectric material 1926 between different interconnect layers 1906-1910 may be the same.

A first interconnect layer 1906 (referred to as Metal 1 or “M1”) may be formed directly on the device layer 1904. In some examples, the first interconnect layer 1906 may include lines 1928A and/or vias 1928B, as shown. The lines 1928A of the first interconnect layer 1906 may be coupled with contacts (e.g., the S/D contacts 1924) of the device layer 1904.

A second interconnect layer 1908 (referred to as Metal 2 or “M2”) may be formed directly on the first interconnect layer 1906. In some examples, the second interconnect layer 1908 may include vias 1928B to couple the lines 1928A of the second interconnect layer 1908 with the lines 1928A of the first interconnect layer 1906. Although the lines 1928A and the vias 1928B are structurally delineated with a line within each interconnect layer (e.g., within the second interconnect layer 1908) for the sake of clarity, the lines 1928A and the vias 1928B may be structurally and/or materially contiguous (e.g., simultaneously filled during a dual-damascene process) in some examples.

A third interconnect layer 1910 (referred to as Metal 3 or “M3”) (and additional interconnect layers, as desired) may be formed in succession on the second interconnect layer 1908 according to similar techniques and/or configurations described in connection with the second interconnect layer 1908 or the first interconnect layer 1906. In some examples, the interconnect layers that are “higher up” in the metallization stack 1919 in the IC device 1900 (i.e., further away from the device layer 1904) may be thicker.

The IC device 1900 may include a solder resist material 1934 (e.g., polyimide or similar material) and one or more conductive contacts 1936 formed on the interconnect layers 1906-1910. In FIG. 19, the conductive contacts 1936 are illustrated as taking the form of bond pads. The conductive contacts 1936 may be electrically coupled with the interconnect structures 1928 and configured to route the electrical signals of the transistor(s) 1940 to other external devices. For example, solder bonds may be formed on the one or more conductive contacts 1936 to mechanically and/or electrically couple a chip including the IC device 1900 with another component (e.g., a circuit board). The IC device 1900 may include additional or alternate structures to route the electrical signals from the interconnect layers 1906-1910; for example, the conductive contacts 1936 may include other analogous features (e.g., posts) that route the electrical signals to external components.

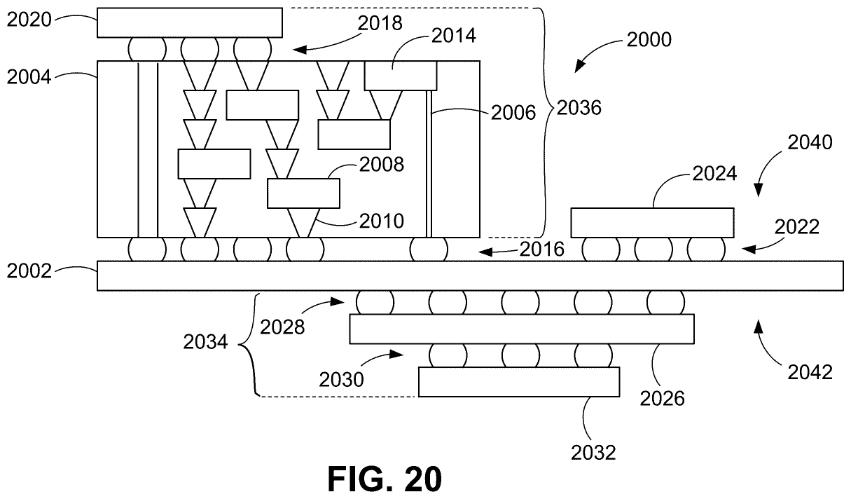

FIG. 20 is a cross-sectional side view of an IC device assembly 2000 that may include the IC package 100 disclosed herein. In some examples, the IC device assembly corresponds to the IC package 100. The IC device assembly 2000 includes a number of components disposed on a circuit board 2002 (which may be, for example, a motherboard). The IC device assembly 2000 includes components disposed on a first face 2040 of the circuit board 2002 and an opposing second face 2042 of the circuit board 2002; generally, components may be disposed on one or both faces 2040 and 2042. Any of the IC packages discussed below with reference to the IC device assembly 2000 may take the form of the example IC package 100 of FIG. 1.

In some examples, the circuit board 2002 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2002. In other examples, the circuit board 2002 may be a non-PCB substrate.

The IC device assembly 2000 illustrated in FIG. 20 includes a package-on-interposer structure 2036 coupled to the first face 2040 of the circuit board 2002 by coupling components 2016. The coupling components 2016 may electrically and mechanically couple the package-on-interposer structure 2036 to the circuit board 2002, and may include solder balls (as shown in FIG. 20), male and female portions of a socket, an adhesive, an underfill material, and/or any other suitable electrical and/or mechanical coupling structure.

The package-on-interposer structure 2036 may include an IC package 2020 coupled to an interposer 2004 by coupling components 2018. The coupling components 2018 may take any suitable form for the application, such as the forms discussed above with reference to the coupling components 2016. Although a single IC package 2020 is shown in FIG. 20, multiple IC packages may be coupled to the interposer 2004; indeed, additional interposers may be coupled to the interposer 2004. The interposer 2004 may provide an intervening substrate used to bridge the circuit board 2002 and the IC package 2020. The IC package 2020 may be or include, for example, a die (the die 1802 of FIG. 18), an IC device (e.g., the IC device 1900 of FIG. 19), or any other suitable component. Generally, the interposer 2004 may spread a connection to a wider pitch or reroute a connection to a different connection. For example, the interposer 2004 may couple the IC package 2020 (e.g., a die) to a set of BGA conductive contacts of the coupling components 2016 for coupling to the circuit board 2002. In the example illustrated in FIG. 20, the IC package 2020 and the circuit board 2002 are attached to opposing sides of the interposer 2004; in other examples, the IC package 2020 and the circuit board 2002 may be attached to a same side of the interposer 2004. In some examples, three or more components may be interconnected by way of the interposer 2004.

In some examples, the interposer 2004 may be formed as a PCB, including multiple metal layers separated from one another by layers of dielectric material and interconnected by electrically conductive vias. In some examples, the interposer 2004 may be formed of an epoxy resin, a fiberglass-reinforced epoxy resin, an epoxy resin with inorganic fillers, a ceramic material, or a polymer material such as polyimide. In some examples, the interposer 2004 may be formed of alternate rigid or flexible materials that may include the same materials described above for use in a semiconductor substrate, such as silicon, germanium, and other group III-V and group IV materials. The interposer 2004 may include metal interconnects 2008 and vias 2010, including but not limited to through-silicon vias (TSVs) 2006. The interposer 2004 may further include embedded devices 2014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2004. The package-on-interposer structure 2036 may take the form of any of the package-on-interposer structures known in the art.

The IC device assembly 2000 may include an IC package 2024 coupled to the first face 2040 of the circuit board 2002 by coupling components 2022. The coupling components 2022 may take the form of any of the examples discussed above with reference to the coupling components 2016, and the IC package 2024 may take the form of any of the examples discussed above with reference to the IC package 2020.

The IC device assembly 2000 illustrated in FIG. 20 includes a package-on-package structure 2034 coupled to the second face 2042 of the circuit board 2002 by coupling components 2028. The package-on-package structure 2034 may include a first IC package 2026 and a second IC package 2032 coupled together by coupling components 2030 such that the first IC package 2026 is disposed between the circuit board 2002 and the second IC package 2032. The coupling components 2028, 2030 may take the form of any of the examples of the coupling components 2016 discussed above, and the IC packages 2026, 2032 may take the form of any of the examples of the IC package 2020 discussed above. The package-on-package structure 2034 may be configured in accordance with any of the package-on-package structures known in the art.

FIG. 21 is a block diagram of an example electrical device 2100 that may include one or more of the example IC package 100. For example, any suitable ones of the components of the electrical device 2100 may include one or more of the device assemblies 2000, IC devices 1900, or dies 1802 disclosed herein, and may be arranged in the example IC package 100. A number of components are illustrated in FIG. 21 as included in the electrical device 2100, but any one or more of these components may be omitted or duplicated, as suitable for the application. In some examples, some or all of the components included in the electrical device 2100 may be attached to one or more motherboards. In some examples, some or all of these components are fabricated onto a single system-on-a-chip (SoC) die.

Additionally, in various examples, the electrical device 2100 may not include one or more of the components illustrated in FIG. 21, but the electrical device 2100 may include interface circuitry for coupling to the one or more components. For example, the electrical device 2100 may not include a display 2106, but may include display interface circuitry (e.g., a connector and driver circuitry) to which a display 2106 may be coupled. In another set of examples, the electrical device 2100 may not include an audio input device 2118 (e.g., microphone) or an audio output device 2108 (e.g., a speaker, a headset, earbuds, etc.), but may include audio input or output device interface circuitry (e.g., connectors and supporting circuitry) to which an audio input device 2118 or audio output device 2108 may be coupled.

The electrical device 2100 may include programmable circuitry 2102 (e.g., one or more processing devices). The programmable circuitry 2102 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 2100 may include a memory 2104, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 2104 may include memory that shares a die with the programmable circuitry 2102. This memory may be used as cache memory and may include embedded dynamic random access memory (eDRAM) or spin transfer torque magnetic random access memory (STT-MRAM).

In some examples, the electrical device 2100 may include a communication chip 2112 (e.g., one or more communication chips). For example, the communication chip 2112 may be configured for managing wireless communications for the transfer of data to and from the electrical device 2100. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 2112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2112 may operate in accordance with other wireless protocols in other examples. The electrical device 2100 may include an antenna 2122 to facilitate wireless communications and/or to receive other wireless communications (such as AM or FM radio transmissions).

In some examples, the communication chip 2112 may manage wired communications, such as electrical, optical, or any other suitable communication protocols (e.g., the Ethernet). As noted above, the communication chip 2112 may include multiple communication chips. For instance, a first communication chip 2112 may be dedicated to shorter-range wireless communications such as Wi-Fi or Bluetooth, and a second communication chip 2112 may be dedicated to longer-range wireless communications such as global positioning system (GPS), EDGE, GPRS, CDMA, WiMAX, LTE, EV-DO, or others. In some examples, a first communication chip 2112 may be dedicated to wireless communications, and a second communication chip 2112 may be dedicated to wired communications.

The electrical device 2100 may include battery/power circuitry 2114. The battery/power circuitry 2114 may include one or more energy storage devices (e.g., batteries or capacitors) and/or circuitry for coupling components of the electrical device 2100 to an energy source separate from the electrical device 2100 (e.g., AC line power).

The electrical device 2100 may include a display 2106 (or corresponding interface circuitry, as discussed above). The display 2106 may include any visual indicators, such as a heads-up display, a computer monitor, a projector, a touchscreen display, a liquid crystal display (LCD), a light-emitting diode display, or a flat panel display.

The electrical device 2100 may include an audio output device 2108 (or corresponding interface circuitry, as discussed above). The audio output device 2108 may include any device that generates an audible indicator, such as speakers, headsets, or earbuds.

The electrical device 2100 may include an audio input device 2118 (or corresponding interface circuitry, as discussed above). The audio input device 2118 may include any device that generates a signal representative of a sound, such as microphones, microphone arrays, or digital instruments (e.g., instruments having a musical instrument digital interface (MIDI) output).

The electrical device 2100 may include GPS circuitry 2116. The GPS circuitry 2116 may be in communication with a satellite-based system and may receive a location of the electrical device 2100, as known in the art.

The electrical device 2100 may include any other output device 2110 (or corresponding interface circuitry, as discussed above). Examples of the other output device 2110 may include an audio codec, a video codec, a printer, a wired or wireless transmitter for providing information to other devices, or an additional storage device.

The electrical device 2100 may include any other input device 2120 (or corresponding interface circuitry, as discussed above). Examples of the other input device 2120 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 2100 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 2100 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that enable the fabrication of thin film capacitors within substrate cores containing a stack of multiple disaggregated glass cores with different CTEs. The thin film capacitors of the example substrate cores disclosed herein provide enhanced power delivery, energy storage, signal coupling, and filtering for such substrate cores. The different CTEs define a CTE gradient that reduces stress within package substrates and, specifically, mitigates against seware failures that are known to arise in substrate with a single, solid glass core with a single CTE. As a result, examples disclosed herein improve yield loss in the fabrication of package substrates and also improve the reliability and/or useful life of IC packages relative to known techniques.

Systems, apparatus, articles of manufacture, and methods for stacks of glass layers including thin film capacitors are disclosed herein. Further examples and combinations thereof include the following:

Example 1 includes a substrate comprising a first glass layer, a dielectric layer on the first glass layer, a second glass layer, the first glass layer between the dielectric layer and the second glass layer, and a capacitor in the dielectric layer.

Example 2 includes the substrate of example 1, wherein the first glass layer has a first coefficient of thermal expansion and the second glass layer has a second coefficient of thermal expansion different than the first coefficient of thermal expansion.

Example 3 includes the substrate of example 1, wherein the dielectric layer is an adhesive layer.

Example 4 includes the substrate of example 1, wherein the dielectric layer is a redistribution layer.

Example 5 includes the substrate of example 1, wherein the capacitor is a thin film capacitor.

Example 6 includes the substrate of example 5, wherein the dielectric layer is a first dielectric layer and further including a second dielectric layer disposed between the first glass layer and the second glass layer.

Example 7 includes the substrate of example 6, wherein the capacitor is a first thin film capacitor and further including a second thin film capacitor in the second dielectric layer, the first thin film capacitor electrically coupled to the second thin film capacitor in parallel.

Example 8 includes the substrate of example 6, wherein the first dielectric layer is a redistribution layer and the second dielectric layer is an adhesive layer.

Example 9 includes the substrate of example 1, further including a third glass layer, the second glass layer between the third glass layer and the first glass layer, and a third dielectric layer between the second glass layer and the third glass layer.

Example 10 includes the substrate of example 9, wherein the capacitor is a first capacitor and further including a second capacitor in the third dielectric layer.

Example 11 includes the substrate of example 9, wherein the first glass layer, the second glass layer, and the third glass layer have an approximately equal thickness.

Example 12 includes the substrate of example 1, wherein the capacitor abuts the first glass layer.

Example 13 includes a device including a first build-up region, a second build-up region, and a core between the first and second build-up regions, the core including a stack of glass layers, and a capacitor.

Example 14 includes the device of example 13, wherein the glass layers include a first glass layer having a first coefficient of thermal expansion, and a second glass layer having a second coefficient of thermal expansion different than the first coefficient of thermal expansion.

Example 15 includes the device of example 14, wherein the glass layers further include a third glass layer, the second glass layer between the first glass layer and the third glass layer, the third glass layer having the first coefficient of thermal expansion.

Example 16 includes the device of example 13, wherein the core further includes a redistribution layer, the capacitor in the redistribution layer.

Example 17 includes the device of example 13, wherein the core further includes an adhesive layer coupling a first glass layer of the stack of glass layers and a second glass layer of the stack of glass layers, the capacitor in the adhesive layer.

Example 18 includes the device of example 13, wherein the capacitor abuts a first glass layer of the stack of glass layers.

Example 19 includes an apparatus comprising a semiconductor die, a package substrate supporting the semiconductor die, the package substrate including a plurality of vertically aligned glass layers, and a capacitor in a layer of the plurality of the vertically aligned glass layers.

Example 20 includes the apparatus of example 19, wherein the capacitor is a thin film capacitor and the thin film capacitor is disposed between a first glass layer of the plurality of the vertically aligned glass layers and a second glass layer of the plurality of the vertically aligned glass layers.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A substrate comprising:
a first glass layer;
a dielectric layer on the first glass layer;
a second glass layer, the first glass layer between the dielectric layer and the second glass layer; and
a capacitor in the dielectric layer.

2. The substrate of claim 1, wherein the first glass layer has a first coefficient of thermal expansion and the second glass layer has a second coefficient of thermal expansion different than the first coefficient of thermal expansion.

3. The substrate of claim 1, wherein the dielectric layer is an adhesive layer.

4. The substrate of claim 1, wherein the dielectric layer is a redistribution layer.

5. The substrate of claim 1, wherein the capacitor is a thin film capacitor.

6. The substrate of claim 5, wherein the dielectric layer is a first dielectric layer and further including a second dielectric layer disposed between the first glass layer and the second glass layer.

7. The substrate of claim 6, wherein the capacitor is a first thin film capacitor and further including a second thin film capacitor in the second dielectric layer, the first thin film capacitor electrically coupled to the second thin film capacitor in parallel.

8. The substrate of claim 6, wherein the first dielectric layer is a redistribution layer and the second dielectric layer is an adhesive layer.

9. The substrate of claim 1, further including:
a third glass layer, the second glass layer between the third glass layer and the first glass layer; and
a third dielectric layer between the second glass layer and the third glass layer.

10. The substrate of claim 9, wherein the capacitor is a first capacitor and further including a second capacitor in the third dielectric layer.

11. The substrate of claim 9, wherein the first glass layer, the second glass layer, and the third glass layer have an approximately equal thickness.

12. The substrate of claim 1, wherein the capacitor abuts the first glass layer.

13. A device including:
a first build-up region;
a second build-up region; and
a core between the first and second build-up regions, the core including:
a stack of glass layers; and
a capacitor.

14. The device of claim 13, wherein the glass layers include:
a first glass layer having a first coefficient of thermal expansion; and
a second glass layer having a second coefficient of thermal expansion different than the first coefficient of thermal expansion.

15. The device of claim 14, wherein the glass layers further include a third glass layer, the second glass layer between the first glass layer and the third glass layer, the third glass layer having the first coefficient of thermal expansion.

16. The device of claim 13, wherein the core further includes a redistribution layer, the capacitor in the redistribution layer.

17. The device of claim 13, wherein the core further includes an adhesive layer coupling a first glass layer of the stack of glass layers and a second glass layer of the stack of glass layers, the capacitor in the adhesive layer.

18. The device of claim 13, wherein the capacitor abuts a first glass layer of the stack of glass layers.

19. An apparatus comprising:
a semiconductor die;
a package substrate supporting the semiconductor die, the package substrate including a plurality of vertically aligned glass layers; and
a capacitor in a layer of the plurality of the vertically aligned glass layers.

20. The apparatus of claim 19, wherein the capacitor is a thin film capacitor and the thin film capacitor is disposed between a first glass layer of the plurality of the vertically aligned glass layers and a second glass layer of the plurality of the vertically aligned glass layers.
